(19) United States
(12) Patent Application Publication
(10) Pub. No.: US 2026/0194596 A1
(43) Pub. Date: Jul. 9, 2026

(54) BATTERY MONITORING DEVICE AND BATTERY MONITORING METHOD

(71) Applicant: Nuvoton Technology Corporation Japan, Kyoto (JP)

(72) Inventors: Misaki MITSUOKA, Kyoto (JP); Susumu YOSHIKAWA, Kyoto (JP); Keiichi FUJII, Kyoto (JP); Hitoshi KOBAYASHI, Kyoto (JP); Akira KAWABE, Kyoto (JP)

(21) Appl. No.: 19/554,267

(22) Filed: Mar. 2, 2026

Related U.S. Application Data
(63) Continuation of application No. PCT/JP2024/031949, filed on Sep. 5, 2024.
(60) Provisional application No. 63/581,466, filed on Sep. 8, 2023.

(30) Foreign Application Priority Data
Sep. 12, 2023 (JP) 2023-147641

(51) Int. Cl. G01R 31/392; G01R 31/36; G01R 31/367; G01R 31/374; G01R 31/3842; G01R 31/389; G01R 31/396

(52) U.S. Cl. CPC G01R 31/392; G01R 31/3648; G01R 31/367; G01R 31/374; G01R 31/3842; G01R 31/389; G01R 31/396

(57) ABSTRACT

A battery monitoring device includes: a first temperature obtainer that obtains a first temperature that is an external temperature of a battery pack that includes a plurality of secondary batteries; a second temperature obtainer that obtains a second temperature that is an internal temperature of each of the plurality of secondary batteries; a third temperature obtainer that obtains a third temperature that includes temperature distribution information of the battery pack; and a determiner that compares the first temperature, the second temperature, and the third temperature and determines, for each of the first temperature, the second temperature, and the third temperature, whether an abnormality is present.

### CROSS REFERENCE TO RELATED APPLICATIONS

This is a continuation application of PCT International Patent Application No. PCT/JP2024/031949 filed on Sep. 5, 2024, designating the United States of America, which is based on and claims priority of Japanese Patent Application No. 2023-147641 filed on Sep. 12, 2023 and U.S. Provisional Patent Application No. 63/581,466 filed on Sep. 8, 2023. The entire disclosures of the above-identified applications, including the specifications, drawings and claims are incorporated herein by reference in their entirety.

### FIELD

The present disclosure relates to a battery monitoring device that monitors the state of a secondary battery and a battery monitoring method therefor.

### BACKGROUND

In recent years, applications that use secondary batteries in battery-equipped devices such as vehicles, energy storage devices, stationary power supply devices, automated guided vehicles (AGVs), robots, and drones have been rapidly increasing. Secondary batteries such as lithium-ion batteries (LiBs) are often adopted for such applications because of their high energy density. Many automotive batteries and storage batteries include a plurality of batteries aligned, and these batteries are connected in series or parallel to constitute a battery pack.

Secondary batteries are known to degrade due to overcharge, overdischarge, or the temperature at which the battery is used. Secondary batteries are also known to degrade over long-term use due to changes in their internal states.

Patent Literature (PTL) 1 discloses a battery monitoring device that monitors the state of a secondary battery. This battery monitoring device measures the voltages, currents, and temperatures of all secondary batteries included in the battery pack to monitor the states of the batteries. PTL 2 discloses a method for diagnosing the degraded state of a secondary battery by measuring the alternating-current impedance of the secondary battery. PTL 3 discloses a method for diagnosing the degraded state of a secondary battery by measuring the internal resistance of the secondary battery.

### CITATION LIST

### Patent Literature

PTL 1: Japanese Patent No. 5403437
PTL 2: Japanese Patent No. 6842212
PTL 3: Japanese Unexamined Patent Application Publication No. 2009-288039

### SUMMARY

### Technical Problem

However, the diagnostic results of the degraded state of a secondary battery obtained using the methods disclosed in the above PTLs may not always reflect the actual situation. Thus, there is a demand for a device that monitors the state of a secondary battery, based on reliable data, for instance.

The present disclosure provides a battery monitoring device, for instance, that can enhance the reliability when monitoring the state of a secondary battery.

### Solution to Problem

A battery monitoring device according to an aspect of the present disclosure includes: a first temperature obtainer that obtains a first temperature that is an external temperature of a battery pack that includes a plurality of secondary batteries; a second temperature obtainer that obtains a second temperature that is an internal temperature of each of the plurality of secondary batteries; a third temperature obtainer that obtains a third temperature that includes temperature distribution information of the battery pack; and a determiner that compares the first temperature, the second temperature, and the third temperature and determines, for each of the first temperature, the second temperature, and the third temperature, whether an abnormality is present.

A battery monitoring method according to an aspect of the present disclosure includes: obtaining a first temperature that is an external temperature of a battery pack that includes a plurality of secondary batteries; obtaining a second temperature that is an internal temperature of each of the plurality of secondary batteries; obtaining a third temperature that includes temperature distribution information of the battery pack; and comparing the first temperature, the second temperature, and the third temperature and determining, for each of the first temperature, the second temperature, and the third temperature, whether an abnormality is present.

### Advantageous Effects

According to, for instance, the battery monitoring device according to the present disclosure, the reliability when monitoring the state of a secondary battery can be enhanced.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 shows capacities of a pristine battery and capacity degraded batteries.

FIG. 2 shows a flow of quantitatively determining the amount of lithium remaining on the negative electrode of a battery.

FIG. 3 shows an equivalent circuit model of a secondary battery and the impedance thereof.

FIG. 4 shows an example of a Nyquist plot.

FIG. 5 is a Nyquist plot of secondary batteries.

FIG. 6 shows a wire-related resistance component, among a plurality of resistance components included in the impedance of a secondary battery.

FIG. 7 shows a state in which the wire-related resistance component is removed from the plurality of resistance components of each secondary battery.

FIG. 8 shows a state in which the wire-related resistance component and a resistance component due to the electrolyte are removed from the plurality of resistance components of each secondary battery.

FIG. 9 shows a state in which the wire-related resistance component, the resistance component due to the electrolyte, a negative-electrode resistance component, and a positive-electrode resistance component are removed from the plurality of resistance components of each secondary battery, and a resistance component due to deposits is extracted.

FIG. 10 shows a flow of deriving a relationship between the resistance component due to deposits and the amount of capacity loss.

FIG. 11 shows relational data between the resistance component due to deposits and the amount of capacity loss.

FIG. 12 is a block diagram showing a battery monitoring device according to Embodiment 1.

FIG. 13 is a perspective view of the battery monitoring device according to Embodiment 1.

FIG. 14 shows an operation flow of the battery monitoring device according to Embodiment 1.

FIG. 15 shows an operation flow of a battery monitoring device according to Variation 1 of Embodiment 1.

FIG. 16 shows a flow for obtaining the battery temperature.

FIG. 17 shows relational data between the resistance component due to deposits and the battery temperature.

FIG. 18 shows the relationship among the resistance component due to deposits, the battery temperature, and the SOH.

FIG. 19 is a block diagram showing a battery monitoring device according to Variation 2 of Embodiment 1.

FIG. 20 shows another example when a battery monitoring device according to Variation 3 of Embodiment 1 measures the impedance of a secondary battery.

FIG. 21 shows yet another example when the battery monitoring device according to Variation 3 of Embodiment 1 measures the impedance of a secondary battery.

FIG. 22 is a block diagram showing a battery monitoring device according to Embodiment 2.

FIG. 23 is a perspective view of the battery monitoring device according to Embodiment 2.

FIG. 24 is a diagram showing relational data between the resistance component due to deposits and the SOH.

FIG. 25 shows relational data between the resistance component due to the electrolyte and the battery temperature.

FIG. 26 shows a state in which the wire-related resistance component and the resistance component due to deposits are removed from the plurality of resistance components of each secondary battery.

FIG. 27 shows a state in which the wire-related resistance component, the resistance component due to deposits, the negative-electrode resistance component, and the positive-electrode resistance component are removed from the plurality of resistance components of each secondary battery, and the resistance component due to the electrolyte is extracted.

FIG. 28 shows an operation flow of the battery monitoring device according to Embodiment 2.

FIG. 29 shows a method of correcting an estimated value of the internal temperature of a secondary battery, which is performed in Variation 1 of Embodiment 2.

FIG. 30 shows the relationship among the resistance component due to deposits, the battery temperature, and the SOH.

FIG. 31 shows the relationship among the wire-related resistance component, the battery temperature, and the SOH.

FIG. 32 shows the relationship among the resistance component due to the electrolyte, the battery temperature, and the SOH.

FIG. 33 is a block diagram showing a battery monitoring device according to Variation 2 of Embodiment 2.

FIG. 34 is a block diagram showing a battery monitoring device according to Embodiment 3.

FIG. 35 is a perspective view of the battery monitoring device according to Embodiment 3.

FIG. 36 shows the appearance of a secondary battery.

FIG. 37 shows the temperature distribution of a secondary battery.

FIG. 38 shows the appearance of a battery pack.

FIG. 39 shows the temperature distributions of the battery pack.

FIG. 40 shows an example of deriving a temperature distribution of the battery pack.

FIG. 41 shows a third temperature obtainer of a battery monitoring device.

FIG. 42 shows a determiner of the battery monitoring device.

FIG. 43 shows an example when no abnormality is present in a first temperature, a second temperature, and a third temperature.

FIG. 44 shows an example in which an abnormality is present in the first temperature.

FIG. 45 shows an example in which an abnormality is present in the second temperature.

FIG. 46 shows an example in which an abnormality is present in the third temperature.

FIG. 47 shows a list of determination results of a determiner.

FIG. 48 shows an operation flow of the battery monitoring device according to Embodiment 3.

FIG. 49 is a block diagram showing part of a battery monitoring device according to a variation of Embodiment 3.

### DESCRIPTION OF EMBODIMENTS

### (Battery Monitoring Device, for Instance, According to Aspects of the Present Disclosure)

Examples of a battery monitoring device, for instance, according to aspects of the present disclosure will be described. Note that aspects of the battery monitoring device are mainly described in Embodiment 3.

A battery monitoring device according to Aspect 1 of the present disclosure includes: a first temperature obtainer that obtains a first temperature that is an external temperature of a battery pack that includes a plurality of secondary batteries; a second temperature obtainer that obtains a second temperature that is an internal temperature of each of the plurality of secondary batteries; a third temperature obtainer that obtains a third temperature that includes temperature distribution information of the battery pack; and a determiner that compares the first temperature, the second temperature, and the third temperature and determines, for each of the first temperature, the second temperature, and the third temperature, whether an abnormality is present.

A battery monitoring device according to Aspect 2 is the battery monitoring device according to Aspect 1 in which the first temperature obtainer may obtain the first temperature, based on an output signal from a thermistor provided on a surface of the battery pack.

A battery monitoring device according to Aspect 3 is the battery monitoring device according to Aspect 1 or 2 in which the second temperature obtainer may obtain the second temperature, based on an impedance of each of the plurality of secondary batteries.

A battery monitoring device according to Aspect 4 is the battery monitoring device according to any one of Aspects 1 to 3 in which the temperature distribution information may include information on an arrangement and temperatures of the plurality of secondary batteries.

A battery monitoring device according to Aspect 5 is the battery monitoring device according to any one of Aspects 1 to 4 in which the third temperature obtainer may obtain the temperature distribution information by inputting a parameter of the battery pack and a usage condition of the battery pack into a battery model created based on information on the plurality of secondary batteries.

A battery monitoring device according to Aspect 6 is the battery monitoring device according to Aspect 5 in which the information on the plurality of secondary batteries may include information on at least one of a material of each of the plurality of secondary batteries, a shape of each of the plurality of secondary batteries, an arrangement of the plurality of secondary batteries, or a cooling system of the plurality of secondary batteries.

A battery monitoring device according to Aspect 7 is the battery monitoring device according to Aspect 5 in which the parameter of the battery pack may include information on at least one of a thermal resistance parameter or a thermal capacity parameter of the battery pack.

A battery monitoring device according to Aspect 8 is the battery monitoring device according to Aspect 5 in which the usage condition of the battery pack may include at least one of a current flowing through each of the plurality of secondary batteries, a voltage applied to each of the plurality of secondary batteries, or a usage environment temperature of the battery pack.

A battery monitoring device according to Aspect 9 is the battery monitoring device according to any one of Aspects 1 to 8 in which the determiner may determine, for each of the first temperature, the second temperature, and the third temperature, whether an abnormality is present by obtaining differences among the first temperature, the second temperature, and the third temperature.

A battery monitoring device according to Aspect 10 is the battery monitoring device according to any one of Aspects 1 to 9 in which the determiner may determine that no abnormality is present in the first temperature, the second temperature, and the third temperature when differences among the first temperature, the second temperature, and the third temperature are each below a predetermined threshold.

A battery monitoring device according to Aspect 11 is the battery monitoring device according to any one of Aspects 1 to 9 in which the determiner may determine that an abnormality is present in measurement of the first temperature when a difference between the second temperature and the first temperature and a difference between the third temperature and the first temperature are each greater than or equal to a first threshold.

A battery monitoring device according to Aspect 12 is the battery monitoring device according to any one of Aspects 1 to 9 in which the determiner may determine that an abnormality is present in measurement of the second temperature when a difference between the first temperature and the second temperature and a difference between the third temperature and the second temperature are each greater than or equal to a second threshold.

A battery monitoring device according to Aspect 13 is the battery monitoring device according to any one of Aspects 1 to 9 in which the determiner may determine that the third temperature does not match an actual temperature distribution when a difference between the first temperature and the third temperature and a difference between the second temperature and the third temperature are each greater than or equal to a third threshold.

A battery monitoring device according to Aspect 14 is the battery monitoring device according to any one of Aspects 1 to 13, which may further include: a safety controller that controls operation of a relay connected in series to the battery pack, based on a determination result of the determiner.

A battery monitoring device according to Aspect 15 is the battery monitoring device according to any one of Aspects 1 to 13, which may further include: a storage that stores relational data indicating, for each of the plurality of secondary batteries, a relationship between a state of the secondary battery and a resistance component that varies with the state of the secondary battery, among a plurality of resistance components included in an impedance of the secondary battery; an impedance obtainer that obtains an impedance of a target secondary battery for monitoring, among the plurality of secondary batteries; and an arithmetic processer that calculates, based on the impedance obtained by the impedance obtainer, a value of a resistance component that varies with a state of the target secondary battery for monitoring, and estimates the state of the target secondary battery for monitoring, based on the value of the resistance component calculated and the relational data.

A battery monitoring device according to Aspect 16 is the battery monitoring device according to Aspect 15 in which the storage may store, as the relational data, a first relational expression indicating, for each of the plurality of secondary batteries, a relationship between an amount of capacity loss of the secondary battery and a first resistance component that varies with the amount of capacity loss of the secondary battery, and the arithmetic processer may calculate a value of the first resistance component of the target secondary battery for monitoring, based on the impedance obtained by the impedance obtainer, and estimate an amount of capacity loss of the target secondary battery for monitoring, based on the value of the first resistance component calculated and the first relational expression.

A battery monitoring device according to Aspect 17 is the battery monitoring device according to Aspect 15 in which the storage may store, as the relational data, a second relational expression indicating, for each of the plurality of secondary batteries, a relationship between an internal temperature of the secondary battery and a second resistance component that varies with the internal temperature of the secondary battery, and the arithmetic processer may calculate a value of the second resistance component of the target secondary battery for monitoring, based on the impedance obtained by the impedance obtainer, and estimate an internal temperature of the target secondary battery for monitoring, based on the value of the second resistance component calculated and the second relational expression.

A battery monitoring method according to Aspect 18 includes: obtaining a first temperature that is an external temperature of a battery pack that includes a plurality of secondary batteries; obtaining a second temperature that is an internal temperature of each of the plurality of secondary batteries; obtaining a third temperature that includes temperature distribution information of the battery pack; and comparing the first temperature, the second temperature, and the third temperature and determining, for each of the first temperature, the second temperature, and the third temperature, whether an abnormality is present.

### (Underlying Knowledge Forming Basis of the Present Disclosure)

The knowledge underlying the present disclosure will be described. In the present disclosure, a lithium-ion battery, which is an example of a secondary battery, is used for description as an example.

First, the reduction in the capacity of a lithium-ion battery and deposits generated on the negative electrode of the lithium-ion battery will be described.

The following expressions represent chemical reactions that occur in a lithium-ion battery.

$$\begin{matrix}[ Math 1 ] & \\ {LiCoO}_{2} ⇔ {Li}_{( 1 - x )} {CoO}_{2} + x {Li}^{+} + x {e}^{-} & ( Expression 1 )\end{matrix}$$

$$\begin{matrix}[ Math 2 ] & \\ 6 x C + x {Li}^{+} + x {e}^{-} ⇔ x {C}_{6} Li & ( Expression 2 )\end{matrix}$$

$$\begin{matrix}[ Math 3 ] & \\ {LiCoO}_{2} + 6 \times C ⇔ {Li}_{( 1 - x )} {CoO}_{2} + x {C}_{6} L i & ( Expression 3 )\end{matrix}$$

Expression 1 above shows the reaction of lithium cobalt oxide (LiCoO₂) at the positive electrode of a lithium-ion battery. Expression 2 shows the reaction of graphite or carbon material at the negative electrode. Expression 3 shows the reaction of the whole battery.

In each expression, the left-to-right direction denotes the charge reaction, and the reverse direction denotes the discharge reaction. As shown in these expressions, lithium ions shuttle between the negative electrode and the positive electrode in a lithium-ion battery, enabling reversible battery reactions.

In lithium-ion batteries, degradation reactions inside the battery are caused by repeatedly charging and discharging the battery or leaving the battery unused for a long period. For example, lithium ions reversibly moving between the positive and negative electrodes are consumed by reactions such as electrolyte decomposition at active-material interfaces, formation of surface films on active materials (solid electrolyte interphase (SEI) growth, for instance), and lithium metal deposition (lithium plating).

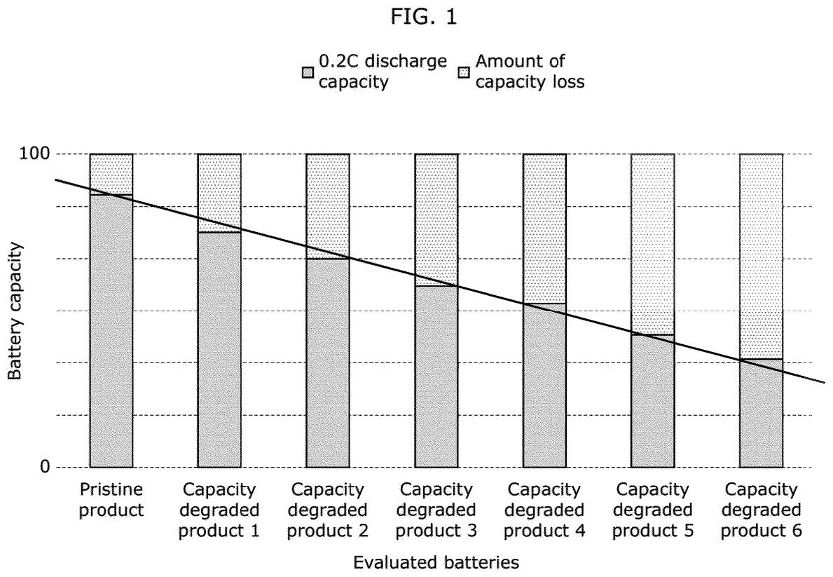

FIG. 1 shows capacities of a pristine battery and capacity degraded batteries.

The figure shows results of measuring 0.2C discharge capacities and amounts of capacity loss of a pristine battery and capacity degraded batteries having a nominal capacity of 10 Ah. Note that the capacity loss of the pristine battery shown in the figure corresponds to the capacity loss caused during charge and discharge in the manufacturing process.

The capacity degraded batteries with progressed capacity degradation are positioned further to the right on the horizontal axis in the figure. As shown in the figure, the more the capacity degradation of a capacity degraded battery progresses, the less the discharge capacity becomes, and in contrast, the greater the amount of capacity loss becomes.

In lithium-ion batteries, deposits are generated on the surface of the negative electrode opposing the positive electrode across the separator. Deposits are generated due to electrolyte reactions at the electrode surface, dissolution of active-material metal components from the positive electrode followed by deposition on the negative electrode, and current-density concentration leading to lithium metal deposition, for instance. When deposits are generated, the pores in the negative-electrode active material are clogged, preventing lithium ions from passing through. Accordingly, lithium is confined in the negative electrode (within the graphite), making reversible reactions difficult to occur and causing the battery capacity to decrease. Physical structural changes of the electrodes during charge and discharge can break the conductive network in the active material, isolating the active material, confining lithium in the negative electrode, and thereby reducing the capacity of the battery.

When deposits are generated as stated above, the impedance of the battery increases. When the impedance increases, a voltage drop (during discharge) or a voltage rise (during charge) corresponding to an increase in impedance appears, leading to a reduction in battery capacity.

As described above, capacity loss occurs due to the battery being repeatedly charged and discharged or being left unused for a long time. Also, capacity loss occurs due to lithium being confined in the negative electrode. Since there is a correlation in which the greater the amount of lithium confined in the negative electrode is, the greater the amount of capacity loss of the secondary battery becomes, the amount of capacity loss is calculated based on the amount of lithium remaining on the negative electrode (the amount of irreversible lithium) in the present disclosure.

The amount of capacity loss is calculated by converting the amount of lithium remaining on the negative electrode into electric capacity using Expression 4 below.

$$\begin{matrix}[ Math 4 ] & \\ Amount of capacity loss = moles of lithium obtained by analysis \div molecular weight of lithium ( 6.941 ) \times 26.8 \times 1000 & ( Expression 4 )\end{matrix}$$

For example, the electric charge corresponding to the movement of one mole of lithium ions is 96,500 coulombs (C), as given by the Faraday constant. Converting the electric charge in coulombs to electric capacity A·hour gives 96,500÷3,600=26.8 (A·hour).

In view of this, the amount of lithium remaining on the negative electrode is converted to moles by unit conversion, and the amount of lithium remaining on the negative electrode is converted to electric capacity, using Expression 4. The converted electric capacity represents the amount of capacity loss of the battery.

The amount of lithium to be substituted into Expression 4 can be obtained by, for example, disassembling a pristine battery (unused battery) and capacity degraded batteries and quantitatively analyzing the amounts of lithium remaining on the negative electrodes.

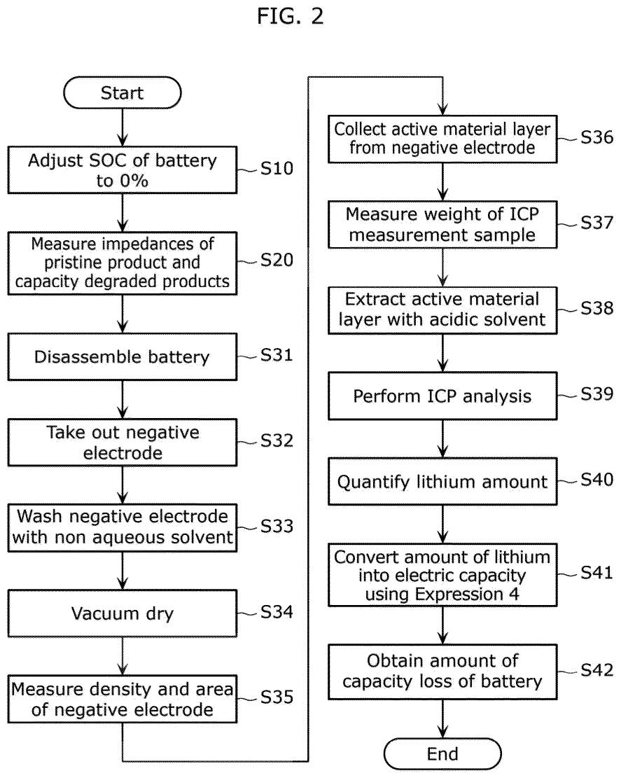

FIG. 2 shows a flow of quantitatively determining the amount of lithium remaining on the negative electrode of a battery. Note that the flow in the figure also includes a step for obtaining the impedance of a battery. The battery in FIG. 2 is a battery used to collect data.

First, a charge-discharge device is used to adjust the state of charge (SOC) of a target battery to SOC 0% (step S10). Note that SOC 0% indicates the state after constant-current (CC) discharge to the minimum operating voltage. For example, when the operating voltage is 2.75 V to 4.2 V, the SOC is adjusted by performing constant current (CC) discharge at a current value of 0.2C down to 2.75 V.

Next, before disassembling the batteries, the impedances of the pristine product and the capacity degraded products are measured (step S20). The impedances are measured to determine the relationship between the impedances of the pristine product and the capacity degraded products and the amounts of capacity loss calculated from the amounts of lithium remaining on the negative electrodes. For example, when the correlation between the battery impedance and the amount of capacity loss is identified, measuring the impedance of a target battery for monitoring makes it possible to obtain the amount of capacity loss of that battery. This will be described later.

To quantify the amount of lithium remaining on the negative electrode, the battery is disassembled inside equipment with controlled dew point (step S31), and the negative electrode is taken out (step S32). Next, the negative electrode is washed with a non-aqueous solvent (for example, diethyl carbonate, ethyl methyl carbonate, or the like) (step S33) and vacuum-dried (step S34), and solvent components are removed. The dew point may be −40° C. or lower.

After vacuum drying, the density and the area of the negative electrode are measured (step S35). Next, using a spatula or the like, an active material layer (or a slurry layer) is collected from the negative electrode (step S36), a sample for inductively coupled plasma (ICP) emission spectroscopic analysis (ICP measurement sample) is prepared, and the weight of the ICP measurement sample is measured (step S37). An extraction solution containing elements is obtained by extracting the above active material layer with an acidic solvent (step S38). Then, ICP analysis is performed on the extraction solution (step S39), and the lithium amount is quantified (step S40).

The amount of capacity loss can be calculated by Expression 4 above. Specifically, the lithium amount obtained by ICP analysis is converted into moles by unit conversion, and the amount of lithium remaining on the negative electrode is converted into electric capacity (step S41). The converted electric capacity represents the amount of capacity loss of the battery. Accordingly, the amount of capacity loss of the battery is obtained (step S42).

Next, a specific impedance that contributes to the amount of capacity loss is extracted from the measured impedances of the pristine product and the capacity degraded products obtained in step S20.

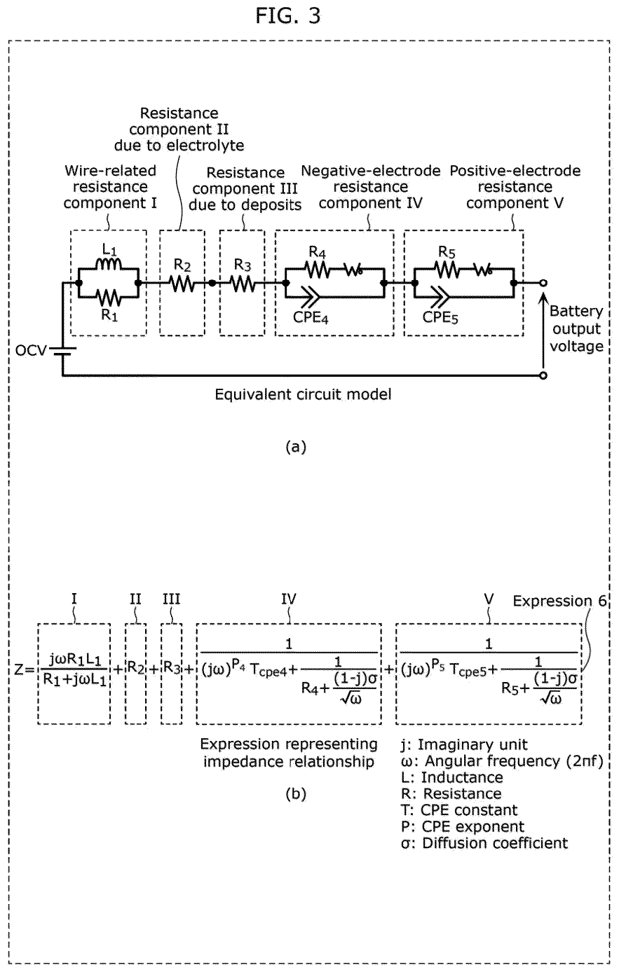

FIG. 3 shows an equivalent circuit model of a secondary battery and the impedance thereof. In FIG. 3, (a) shows an equivalent circuit model of a secondary battery, and (b) shows an expression representing a relationship of the impedance of the secondary battery.

As shown in (a) of FIG. 3, the equivalent circuit of a secondary battery is a circuit that includes a plurality of resistance components. As shown in (b) of FIG. 3, the impedance of a secondary battery includes a plurality of resistance components. The plurality of resistance components shown in FIG. 3 are: wire-related resistance component I, resistance component II due to the electrolyte, resistance component III due to deposits, negative-electrode resistance component IV, and positive-electrode resistance component V.

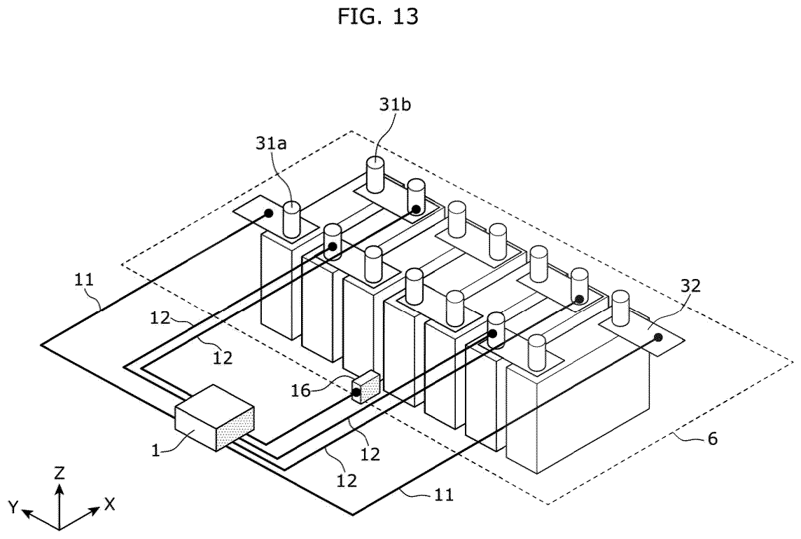

Wire-related resistance component I is determined by the impedance of a wire and the impedance between the wire and the secondary battery. Wire-related resistance component I arises from electrical resistance (including contact resistance and welding resistance) when electrons move. For example, wire-related resistance component I arises from metal such as wires, battery terminals 31, bus bars 32 (refer to FIG. 13), or current-collecting foil inside the secondary battery. Thus, wire-related resistance component I does not contribute to the electrochemical capacity loss of the secondary battery. The value of wire-related resistance component I is observed on the high-frequency side (for example, at least 1 kHz) and can be measured by alternating-current (AC) impedance measurement or direct-current (DC) resistance measurement.

Resistance component II due to the electrolyte is the impedance that arises due to migration resistance in the electrolyte of the secondary battery. Resistance component II due to the electrolyte is generated due to the physical resistance when lithium ions move. Resistance component II due to the electrolyte is affected by factors such as the electrolyte salt concentration, the ionic conductivity of the non-aqueous electrolyte, the electrolyte viscosity (specific gravity), and the pore size of the separator (how easy it is for a lithium ion to pass through).

Resistance component III due to deposits is the impedance resulting from deposit resistance on the electrode surface. Deposits are generated as by-products of electrochemical reactions such as electrolyte reactions at active-material surfaces, deposition of the active material dissolved from the positive electrode on the negative electrode of metal components, and lithium metal deposition caused by the concentrated current density. The generation of such deposits increases the impedance of the secondary battery and, at the same time, the pores in the negative-electrode active material are clogged so that lithium ions are prevented from passing through and lithium is trapped in the negative electrode (inside graphite). These deposits increase as the secondary battery is repeatedly charged and discharged or is left unused for a long period.

Negative-electrode resistance component IV indicates the impedance of the negative electrode of the secondary battery. Positive-electrode resistance component V indicates the impedance of the positive electrode of the secondary battery. Such resistance components IV and V are the internal or surface impedances of the active material, conductive additives, and the like that are included in the electrodes.

Among a plurality of resistance components, compared with wire-related resistance component I, resistance component II due to the electrolyte, negative-electrode resistance component IV, and positive-electrode resistance component V, resistance component III due to deposits contributes to the capacity loss of the secondary battery.

Since it is difficult to directly measure the impedance of resistance component III due to deposits, in this example, the impedance of resistance component III due to deposits is obtained by subtracting the impedance of another resistance component from the measured impedance of the secondary battery. In this example, a Nyquist plot of the secondary battery is used to obtain resistance component III due to deposits.

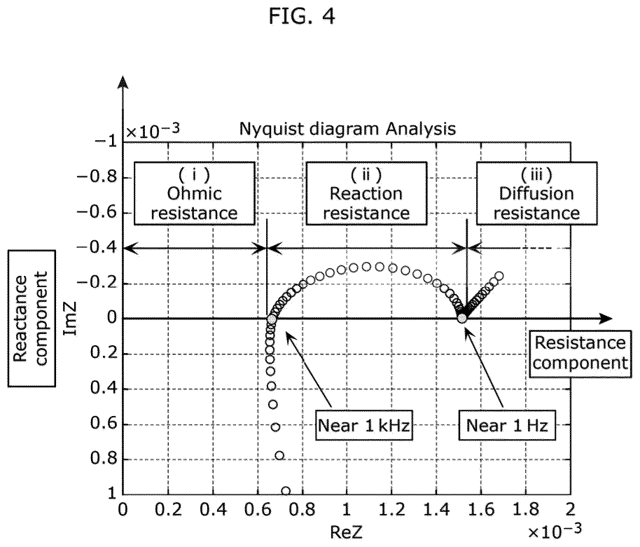

FIG. 4 shows an example of a Nyquist plot.

A Nyquist plot is a diagram that plots a change in impedance on the complex plane when a frequency sweep is applied to the secondary battery. In FIG. 4, the horizontal axis represents real part ReZ of complex impedance Z, and the vertical axis represents imaginary part ImZ of complex impedance Z.

Region (i) is an ohmic resistance region of the secondary battery, and the ohmic resistance corresponds to wire-related resistance component I, resistance component II due to the electrolyte, and resistance component III due to deposits. Region (ii) is the reaction resistance region of the secondary battery, and corresponds to negative-electrode resistance component IV and positive-electrode resistance component V. Region (iii) is a diffusion resistance region of the secondary battery, and reflects the influence of the Warburg impedance of the secondary battery.

Below, a procedure for extracting resistance component III due to deposits is described with reference to the Nyquist plot. Note that this procedure is applied both when extracting resistance component III due to deposits from the measured impedances of a pristine secondary battery and degraded secondary batteries and when extracting resistance component III due to deposits from the measured impedance of a target secondary battery for monitoring.

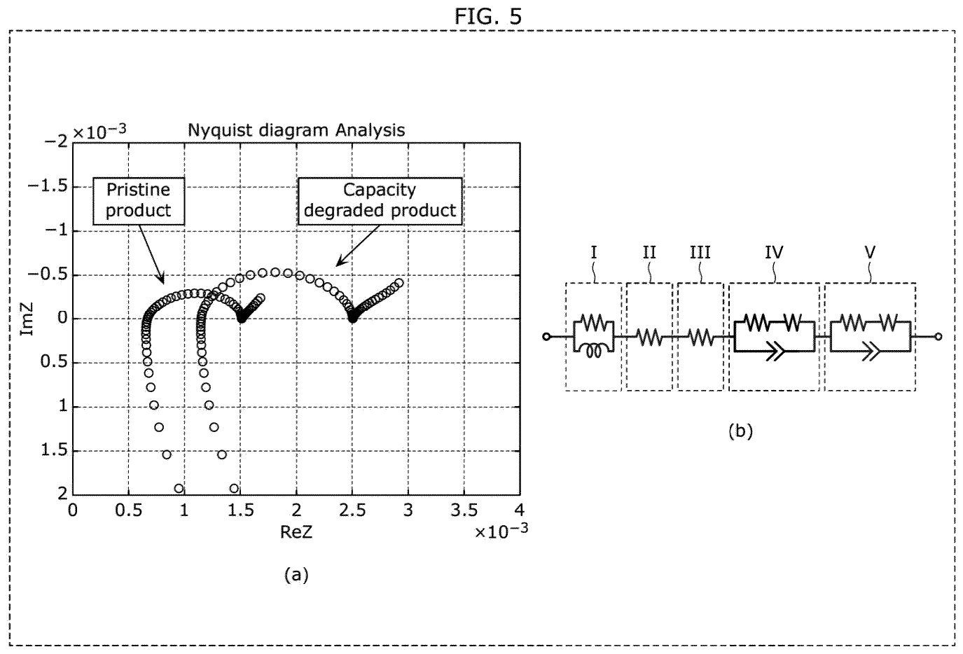

FIG. 5 is a Nyquist plot of secondary batteries. The figure shows changes in impedance of a pristine secondary battery and a degraded secondary battery.

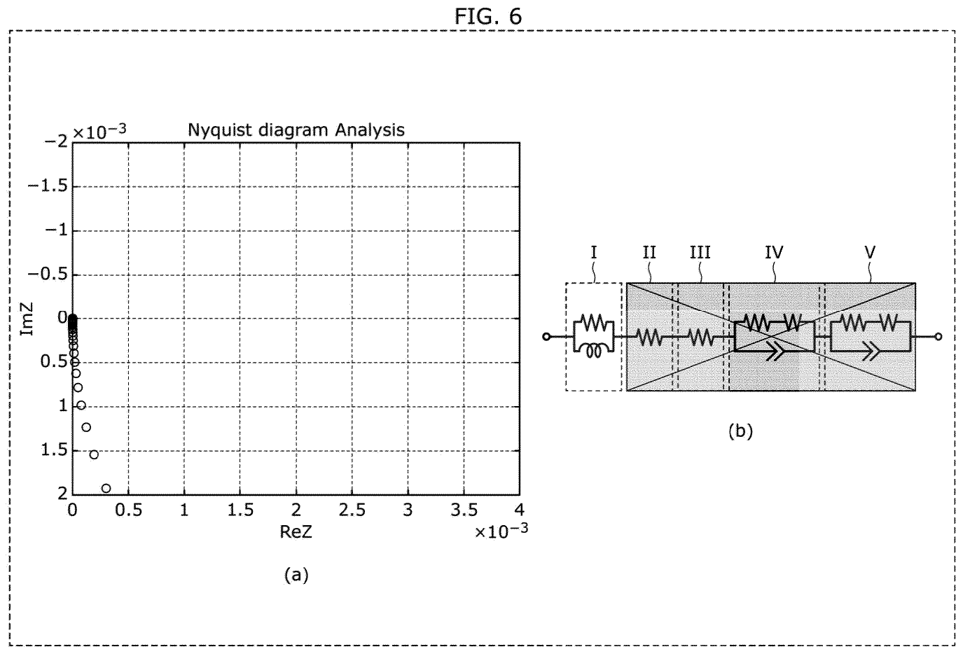

FIG. 6 shows wire-related resistance component I among the plurality of resistance components included in the impedance of a secondary battery. Part (a) of FIG. 6 shows a Nyquist plot showing changes in impedance of wire-related resistance component I. Part (b) of FIG. 6 shows an equivalent circuit of a secondary battery.

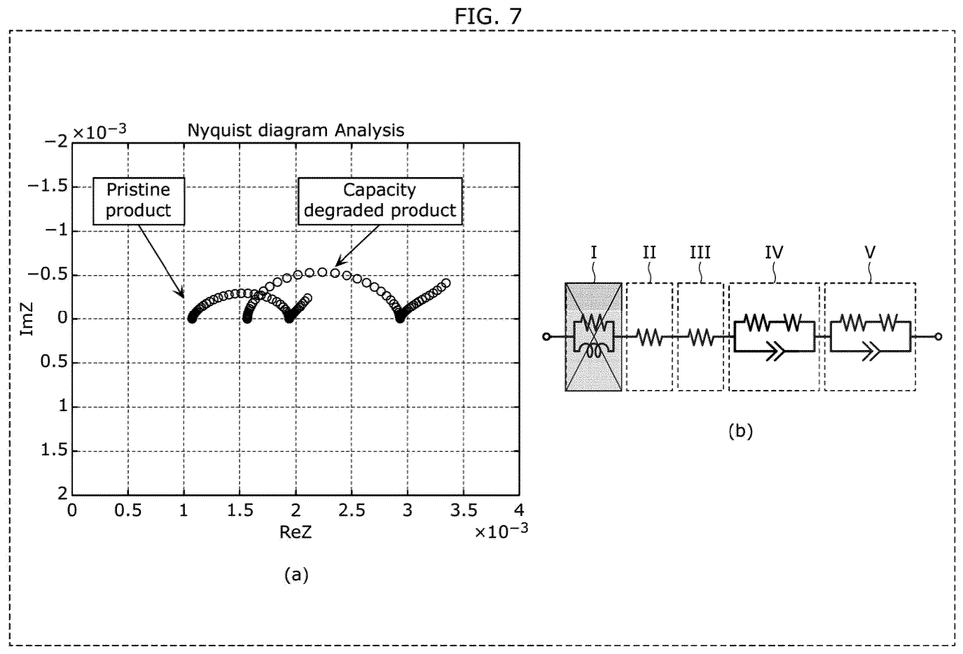

FIG. 7 shows the state in which wire-related resistance component I is removed from the plurality of resistance components of each secondary battery. Part (a) of FIG. 7 shows a Nyquist plot showing changes in impedance of resistance component II due to the electrolyte, resistance component III due to deposits, negative-electrode resistance component IV, and positive-electrode resistance component V. Part (b) of FIG. 7 shows an equivalent circuit of resistance component II due to the electrolyte, resistance component III due to deposits, negative-electrode resistance component IV, and positive-electrode resistance component V.

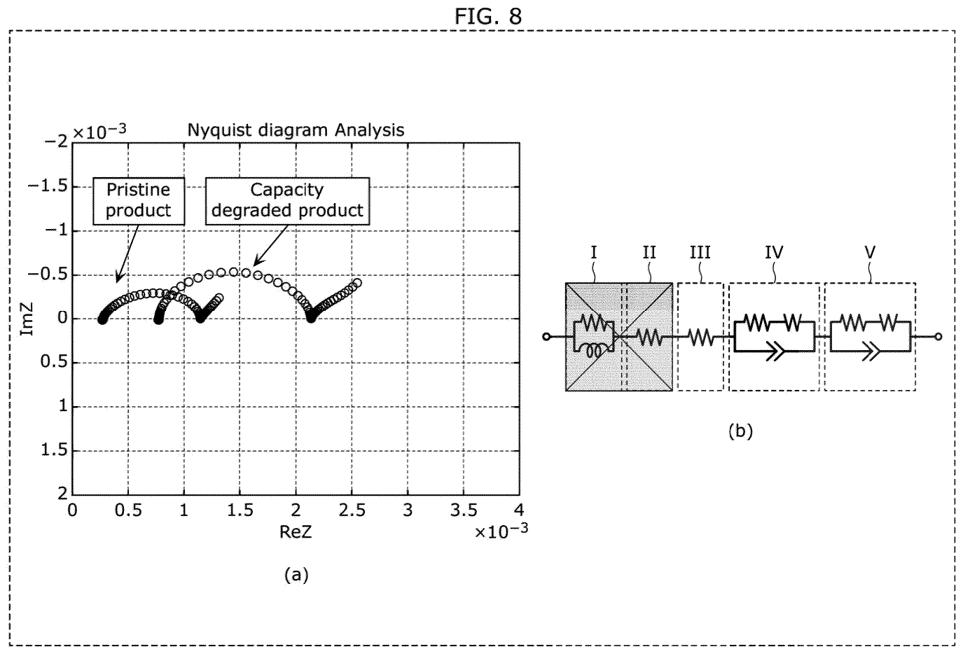

FIG. 8 shows the state in which wire-related resistance component I and resistance component II due to the electrolyte are removed from the plurality of resistance components of each secondary battery. Part (a) of FIG. 8 shows a Nyquist plot showing changes in impedance of resistance component III due to deposits, negative-electrode resistance component IV, and positive-electrode resistance component V. Part (b) of FIG. 8 shows an equivalent circuit of resistance component III due to deposits, negative-electrode resistance component IV, and positive-electrode resistance component V. Note that the method for obtaining resistance component II due to the electrolyte will be described later.

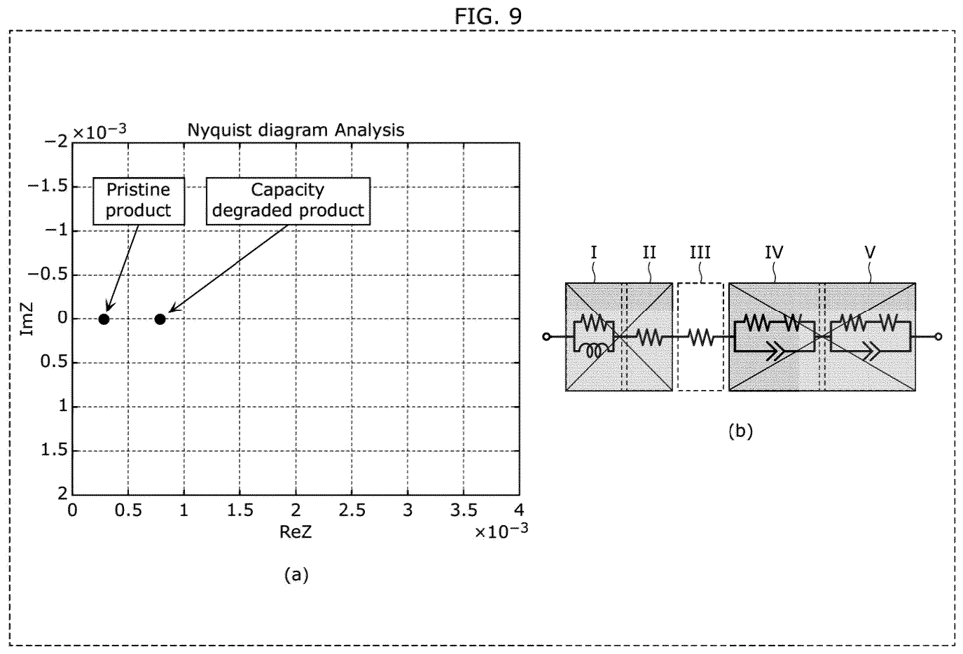

FIG. 9 shows the state in which wire-related resistance component I, resistance component II due to the electrolyte, negative-electrode resistance component IV, and positive-electrode resistance component V are removed from the plurality of resistance components of each secondary battery, and resistance component III due to deposits is extracted. Part (a) of FIG. 9 shows a Nyquist plot showing changes in impedance of resistance component III due to deposits. As shown in the figure, the value of resistance component III due to deposits is represented by only the real part of complex impedance Z. Part (b) of FIG. 9 shows an equivalent circuit of resistance component III due to deposits.

As described above, resistance component III due to deposits is extracted from the impedance of a secondary battery by removing wire-related resistance component I, resistance component II due to the electrolyte, negative-electrode resistance component IV, and positive-electrode resistance component V.

Resistance component III due to deposits is a parameter that contributes to the capacity loss of a secondary battery and is a value that changes with the amount of capacity loss of the secondary battery. In view of this, if, for example, the relationship between resistance component III due to deposits and the amount of capacity loss can be understood in advance, it is conceivable that the capacity loss of the target secondary battery for monitoring can be estimated based on the impedance of the secondary battery.

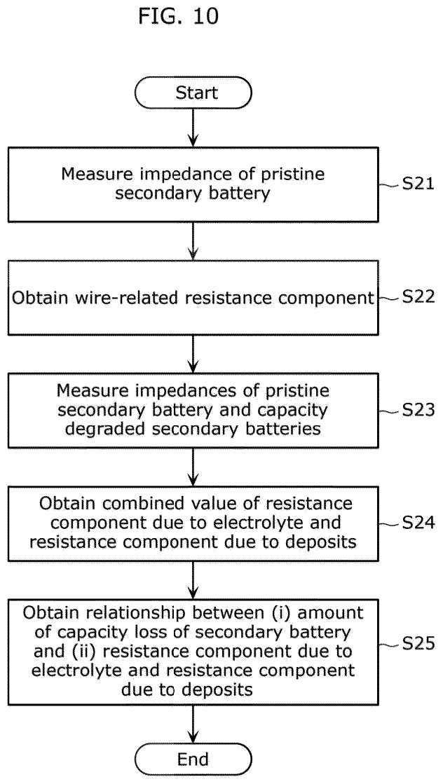

FIG. 10 is a diagram showing the flow for deriving the relationship between resistance component III due to deposits and the amount of capacity loss. The secondary battery in FIG. 10 is a secondary battery used to collect data.

FIG. 10 shows processing corresponding to step S20 in FIG. 2 and the subsequent processing. Below, steps S21 to S24 are shown as the processing corresponding to step S20 in FIG. 2, and step S25 is shown as the subsequent processing.

First, the impedance of a pristine secondary battery is measured (step S21). Then, curve fitting is performed on the Nyquist plot of the impedance obtained from the pristine battery, to obtain wire-related resistance component I (step S22). Note that wire-related resistance component I varies for each secondary battery due to differences such as wire length, wire type, bus bar length, and welding resistance at connection locations, and thus individual measurement and calculation of the impedance value are to be conducted.

Next, the impedances of the pristine secondary battery and a plurality of capacity degraded secondary batteries are measured (step S23). Note that step S23 may be conducted before steps S21 and S22.

Next, wire-related resistance component I, negative-electrode resistance component IV, and positive-electrode resistance component V are removed from each of the measured impedances. Note that negative-electrode resistance component IV and positive-electrode resistance component V are obtained by performing curve fitting on the Nyquist plot. The value resulting from subtracting these resistance components from the measured impedance corresponds to the combined value of resistance component II due to the electrolyte and resistance component III due to deposits. Accordingly, the combined value of resistance component II due to the electrolyte and resistance component III due to deposits is obtained (step S24).

Next, the amount of capacity loss of a secondary battery obtained in step S42 in FIG. 2 and the combined value of resistance component II due to the electrolyte and resistance component III due to deposits obtained in step S24 are plotted on a graph. Accordingly, the relationship between (i) the amount of capacity loss of a secondary battery and (ii) resistance component II due to the electrolyte and resistance component III due to deposits is obtained (step S25).

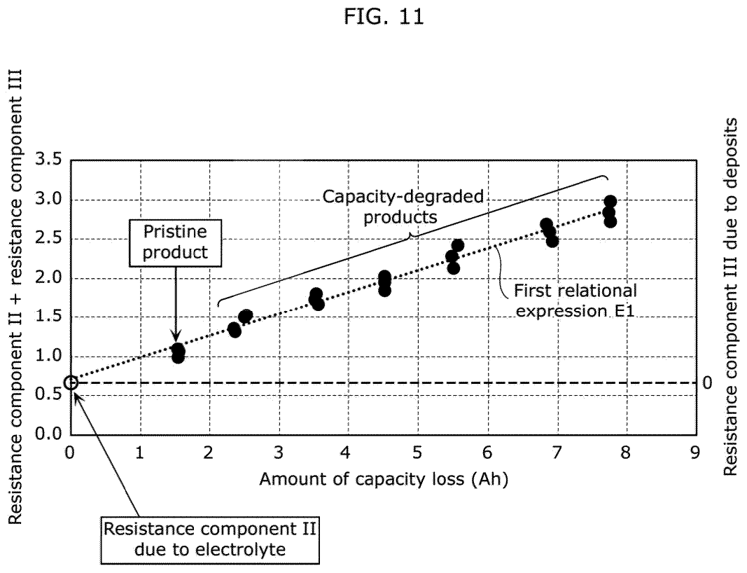

FIG. 11 shows relational data between resistance component III due to deposits and the amount of capacity loss. In the figure, the horizontal axis represents the amount of capacity loss of a secondary battery, and the left vertical axis represents the combined value of resistance component II due to the electrolyte and resistance component III due to deposits. Note that the right vertical axis represents resistance component III due to deposits.

As shown in the figure, (i) the amount of capacity loss of a secondary battery and (ii) resistance component II due to the electrolyte and resistance component III due to deposits exhibit a correlation expressed by first relational expression E1. First relational expression E1 is, for example, obtained by the least squares method and is represented in a linear expression. In this example, the slope of first relational expression E1 represents the relationship between the amount of capacity loss and resistance component III due to deposits. Furthermore, in the figure, the value when extending the straight line that connects the plots to reach a point where the capacity loss is zero shows resistance component II due to the electrolyte. In this example, the intercept of first relational expression E1 is the value (fixed value) of resistance component II due to the electrolyte.

When focusing solely on resistance component III due to deposits with resistance component II due to the electrolyte being excluded, first relational expression E1 corresponds to relational data represented by the horizontal axis and the right vertical axis in FIG. 11.

Using these flows, first relational expression E1 indicating the relationship between resistance component III due to deposits and the amount of capacity loss of a secondary battery is obtained. Accordingly, the amount of capacity loss of a target secondary battery for monitoring can be obtained by measuring the impedance of the target secondary battery for monitoring, extracting, from that impedance, resistance component III due to deposits which contributes to the amount of capacity loss, and substituting extracted resistance component III into first relational expression E1.

Furthermore, the State of Health (SOH) can be calculated based on Expression 5 in the following.

$$\begin{matrix}[ Math 5 ] & \\ SOH = ( initial capacity ) - ( amount of capacity loss ) & ( Expression 5 )\end{matrix}$$

The SOH of the target secondary battery for monitoring is calculated by subtracting the amount of capacity loss from the initial capacity (the capacity set at the start of battery use), as shown in Expression 5 above. Note that when the full-charge capacity (Ah) of a pristine product is defined as 100%, the SOH is the proportion of the full-charge capacity (Ah) of the degraded product.

It is considered that the reliability when monitoring the state of a secondary battery or specifically, the reliability when monitoring the amount of capacity loss and the SOH can be enhanced by performing these processes.

In the following, embodiments are to be specifically described with reference to the figures. Note that the embodiments described below each show a particular example of the present disclosure. The numerical values, shapes, materials, elements, the arrangement and connection of the elements, steps, and the processing order of the steps, for instance, described in the following embodiments are mere examples, and thus are not intended to limit the present disclosure. Among the elements in the following embodiments, elements not recited in any of the independent claims are described as optional elements.

Note that the figures are schematic diagrams, and do not necessarily provide strictly accurate illustration. In the figures, the same reference sign is given to a substantially same configuration, and a redundant description thereof may be omitted or simplified.

### Embodiment 1

### [Configuration of Battery Monitoring Device]

An outline configuration of a battery monitoring device according to Embodiment 1 will be described. Below, an example when the battery monitoring device is applied to a power system of a vehicle (for example, a hybrid vehicle or an electric vehicle) is described.

Note that hereafter resistance component III due to deposits may be referred to as a first resistance component. Resistance component III due to deposits is an example of the first resistance component.

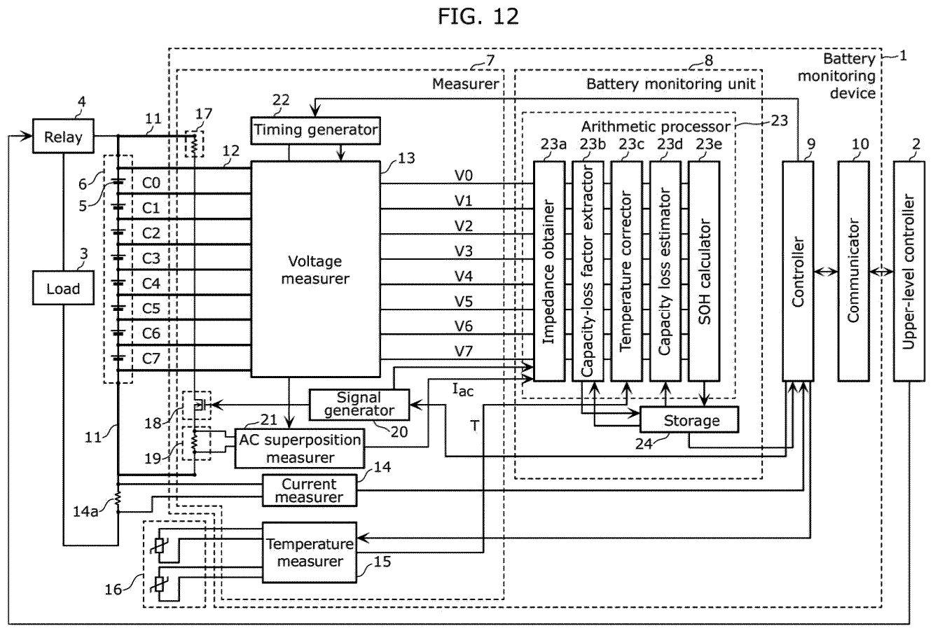

FIG. 12 is a schematic configuration diagram showing an example of battery monitoring device 1 according to Embodiment 1. FIG. 13 is a perspective view of battery monitoring device 1 according to Embodiment 1. Note that FIG. 12 also shows upper-level controller 2, load 3, and relay 4 in addition to battery monitoring device 1. FIG. 13 also shows battery pack 6, thermistor 16, current-application lines 11, and voltage-detection lines 12, for instance, in addition to battery monitoring device 1.

As shown in FIG. 12, battery monitoring device 1 is connected to battery pack 6, in which a plurality of secondary batteries 5 (configured of batteries C0 to C7, for example) are combined and connected. Secondary batteries 5 are, for example, lithium-ion batteries, but are not limited thereto and may be other batteries such as nickel-hydrogen batteries.

Relay 4 that switches the connection between battery pack 6 and load 3 (corresponding to a motor, an inverter, or an accelerator, for example) on and off is provided between battery pack 6 and load 3. In a vehicle, applications operate according to the on/off of connection between battery pack 6 and load 3 switched by relay 4. Note that when secondary batteries 5 are energy storage batteries, load 3 may be a charger.

Battery monitoring device 1 is a device that obtains the internal impedances of secondary batteries 5, to monitor the states of secondary batteries 5. For example, battery monitoring device 1 measures and obtains the internal AC impedances of secondary batteries 5. Also, for example, battery monitoring device 1 measures and obtains the internal impedances (for example, internal AC impedances) of secondary batteries 5.

Battery monitoring device 1 includes measurer 7, battery monitoring unit 8, controller 9, and communicator 10.

Battery monitoring device 1 measures internal AC impedances of secondary batteries 5 (for example, individual internal AC impedances of secondary batteries 5), based on the AC current applied to battery pack 6 and the voltages of secondary batteries 5 (for example, individual voltages of secondary batteries 5) included in battery pack 6. For example, battery monitoring device 1 uses electrochemical impedance spectroscopy (EIS) to measure the internal AC impedance characteristics of secondary batteries 5 and monitors the states of secondary batteries 5 in real time.

Battery pack 6 and battery monitoring device 1 are connected by current-application lines 11 and voltage-detection lines 12.

Battery pack 6 functions as a power source for upper-level controller 2 and load 3 (or a charger) and supplies power to upper-level controller 2 and load 3 (or the charger).

Measurer 7 is an example of a Cell Management Unit (CMU). Measurer 7 includes voltage measurer 13 that measures voltages of battery pack 6, current measurer 14 that measures a current therethrough, and temperature measurer 15 that measures a temperature of battery pack 6. Measurer 7 includes reference resistor 14a, thermistor 16 that measures the external temperature of a battery, load resistor 17, switching element 18, shunt resistor (AC superposition) 19, signal generator 20, AC superposition measurer (voltage conversion) 21, and timing generator 22.

Controller 9, together with voltage measurer 13, signal generator 20, AC superposition measurer 21, and timing generator 22, constitute a functional configuration for measuring the internal AC impedance of battery pack 6 (specifically, secondary batteries 5 included in battery pack 6).

Load resistor 17, switching element 18, and shunt resistor 19 constitute a circuit for measuring the internal AC impedance of battery pack 6.

Switching element 18 can be turned on/off at specific frequencies, by controller 9 controlling signal generator 20, which sweeps an AC signal. Accordingly, AC currents at specific frequencies are output from battery pack 6.

AC superposition measurer 21 measures the voltage generated across shunt resistor 19 (that is, the voltage converted from the AC current output from battery pack 6).

Load resistor 17 and battery pack 6, and shunt resistor 19 and battery pack 6 are connected via current-application lines 11. Load resistor 17 and shunt resistor 19 are included in battery monitoring device 1, and battery monitoring device 1 and battery pack 6 are connected via current-application lines 11. Current-application lines 11 are wires for applying an AC current to battery pack 6, and are, for example, conductors.

Voltage measurer 13 measures the voltages of secondary batteries 5 included in battery pack 6. Voltage measurer 13 may measure the voltages of all of secondary batteries 5 included in battery pack 6. Alternatively, voltage measurer 13 may measure the voltages of one or more (for example, at least two) of secondary batteries 5 included in battery pack 6, or stated differently, battery pack 6 may include one or more secondary batteries 5 whose voltages are not measured by voltage measurer 13.

Voltage measurer 13 measures the voltages of secondary batteries 5 included in battery pack 6 at the measurement timing set by timing generator 22 so that the voltages are measured at the same timing.

Voltage measurer 13 is connected to secondary batteries 5 via voltage-detection lines 12 and measures the voltages of secondary batteries 5 (for example, the individual voltages of secondary batteries 5).

Voltage-detection lines 12 are wires for detecting the voltages of secondary batteries 5 (for example, the individual voltages of secondary batteries 5).

As shown in FIG. 13, voltage-detection lines 12 are connected to positive-electrode battery terminals 31a and negative-electrode battery terminals 31b of secondary batteries 5. In the example shown in FIG. 13, sixteen voltage-detection lines 12 are provided for eight batteries C0 to C7. Voltage-detection lines 12 are, for example, conductors.

Temperature measurer 15 measures the battery temperature using thermistor 16. Thermistor 16 is, for example, provided on the side surface of battery pack 6, at a terminal portion of battery pack 6, on one of bus bars 32 that connect secondary batteries in series or parallel (refer to FIG. 13), for instance. Thermistor 16 may be a temperature sensor for which another element such as a thermocouple is used.

Battery monitoring unit 8 shown in FIG. 12 is a Battery Management Unit (BMU) and includes arithmetic processor 23 and storage 24.

Storage 24 stores in advance relational data indicating the relationship between the state of secondary battery 5 and a resistance component that varies with the state of secondary battery 5. Specifically, storage 24 stores first relational expression E1 indicating the relationship between the amount of capacity loss of secondary battery 5 and a first resistance component that varies with the amount of capacity loss of secondary battery 5. In this example, the first resistance component is resistance component III due to deposits that are deposited on the surface of the negative electrode of secondary battery 5. Note that first relational expression E1 is an example of relational data.

As described above, first relational expression E1 stored in storage 24 is derived based on the amounts of capacity loss of secondary batteries 5 whose capacities are less than or equal to the capacity of a pristine product, and on first resistance components obtained by measuring the impedances of secondary batteries 5 in advance.

The amount of capacity loss of secondary battery 5 in first relational expression E1 is calculated based on the amount of irreversible lithium remaining on the negative electrode of secondary battery 5. Furthermore, the first resistance component in first relational expression E1 is obtained by removing, from the impedance of secondary battery 5 whose capacity is less than or equal to the capacity of a pristine product: wire-related resistance component I determined by a resistance component of a wire connected to secondary battery 5 and a resistance component between the wire and secondary battery 5; resistance component II based on migration resistance in the electrolyte of secondary battery 5; and negative-electrode resistance component IV and positive-electrode resistance component V of secondary battery 5.

Storage 24 also stores the value of resistance component II due to the electrolyte obtained in the process of deriving first relational expression E1, and the value of wire-related resistance component I obtained in step S22 in FIG. 10. These values of resistance component II due to the electrolyte and wire-related resistance component I are fixed values that do not vary with the degradation of secondary battery 5.

Arithmetic processor 23 obtains information on the state (the amount of capacity loss and the SOH) of secondary battery 5 by performing arithmetic processing on information output from measurer 7 and information stored in storage 24. Note that such a battery state may include abnormalities (failures and degradations) of the battery.

In the present embodiment, arithmetic processor 23 calculates the value of a resistance component that varies with the state of target secondary battery 5 for monitoring, based on the impedance measured and obtained by measurer 7 and estimates the state of secondary battery 5, using the calculated value of the resistance component and the relational data stored in storage 24.

To perform the above processing, arithmetic processor 23 includes impedance obtainer 23a, capacity-loss factor extractor 23b, temperature corrector 23c, capacity loss estimator 23d, and SOH calculator 23e.

Impedance obtainer 23a, capacity-loss factor extractor 23b, temperature corrector 23c, capacity loss estimator 23d, and SOH calculator 23e constitute a functional configuration for estimating the amounts of capacity loss and the SOH of batteries C0 to C7.

Impedance obtainer 23a obtains impedances Z0 to Z7 of batteries C0 to C7, based on voltages V0 to V7 of batteries C0 to C7 measured by voltage measurer 13 and current value Iac measured and converted into voltage by AC superposition measurer 21. Impedances Z0 to Z7 are complex numbers, and real part ReZ and imaginary part ImZ are calculated for each of batteries C0 to C7. A calculated complex impedance is a ratio, at each frequency, of the voltage measured by voltage measurer 13 to the current measured by AC superposition measurer 21 when signal generator 20 outputs an AC current from battery pack 6 at the frequency. Nyquist plots as shown in FIG. 5 to FIG. 9 can be obtained by plotting the complex impedances on the complex plane. Impedance obtainer 23a outputs calculated complex impedance values Z0 to Z7 of batteries C0 to C7 to capacity-loss factor extractor 23b.

Capacity-loss factor extractor 23b extracts resistance component III due to deposits, which is a capacity loss factor of each secondary battery 5, based on complex impedance values Z0 to Z7 of batteries C0 to C7.

Arithmetic processor 23 performs the following processing to estimate the amount of capacity loss of secondary battery 5, based on resistance component III due to deposits, which is the first resistance component.

For example, capacity-loss factor extractor 23b calculates the value of the first resistance component of target secondary battery 5 for monitoring, based on the impedance obtained by impedance obtainer 23a. When calculating the value of the first resistance component, arithmetic processor 23 obtains the value of the first resistance component by removing, from the impedance obtained by impedance obtainer 23a: wire-related resistance component I determined by the resistance component of a wire connected to secondary battery 5 and the resistance component between the wire and secondary battery 5; resistance component II based on migration resistance in the electrolyte of secondary battery 5; and negative-electrode resistance component IV and positive-electrode resistance component V of secondary battery 5.

Note that wire-related resistance component I is a value obtained in step S22 in FIG. 10 and is stored in storage 24 in advance. Resistance component II due to the electrolyte is a value derived from first relational expression E1 in FIG. 11 and is stored in storage 24 in advance. Negative-electrode resistance component IV and positive-electrode resistance component V are values obtained by curve-fitting the Nyquist plot that represents changes in impedance of secondary battery 5. Note that the above has shown an example in which the impedance of resistance component II due to the electrolyte is derived from first relational expression E1, but it is not limiting. For example, resistance component II due to the electrolyte can also be calculated from the ionic conductivity of the electrolyte used in a secondary battery. Thus, resistance component II due to the electrolyte stored in storage 24 may be a value calculated from the ionic conductivity.

Information on the first resistance component (resistance component III due to deposits) extracted by capacity-loss factor extractor 23b is output to temperature corrector 23c or capacity loss estimator 23d.

Capacity loss estimator 23d estimates the amount of capacity loss of secondary battery 5, based on the value of the first resistance component and first relational expression E1 stored in storage 24. Specifically, capacity loss estimator 23d derives the amount of capacity loss of secondary battery 5 by substituting the value of the first resistance component into first relational expression E1. The derived amount of capacity loss is output to SOH calculator 23e.

Note that capacity loss estimator 23d may estimate the amount of capacity loss, based on relational data between the value of the first resistance component after temperature correction is performed by temperature corrector 23c and the amount of capacity loss. Temperature correction will be described in Variation 1 below.

SOH calculator 23e estimates the current capacity of secondary battery 5 by subtracting the amount of capacity loss estimated by arithmetic processor 23 from the initial capacity of secondary battery 5. For example, SOH calculator 23e uses Expression 5 above to calculate the SOH from a difference between the initial capacity (the capacity set at the start of battery use) and the amount of capacity loss. Information on the SOH calculated by SOH calculator 23e is stored in storage 24.

Information on the amounts of capacity loss, the SOH, and abnormalities of batteries C0 to C7 obtained by arithmetic processor 23 are notified to upper-level controller 2 via storage 24, controller 9, and communicator 10. Communicator 10 is a communication module and transmits the above information to upper-level controller 2 in a wireless or wired manner. Upper-level controller 2 executes control according to the amounts of capacity loss, the SOH, and the abnormalities, for instance, of secondary batteries 5, which have been notified, in a vehicle.

Battery monitoring device 1 according to the present embodiment calculates the value of resistance component III due to deposits, based on the impedance obtained by impedance obtainer 23a. Then, the state of secondary battery 5 is estimated based on the value of resistance component III due to deposits and first relational expression E1. As described above, the reliability when monitoring the state of secondary battery 5 can be enhanced by monitoring the state of secondary battery 5 based on, for instance, reliable data.

### [Operation of Battery Monitoring Device]

The operation of battery monitoring device 1 according to Embodiment 1 will be described.

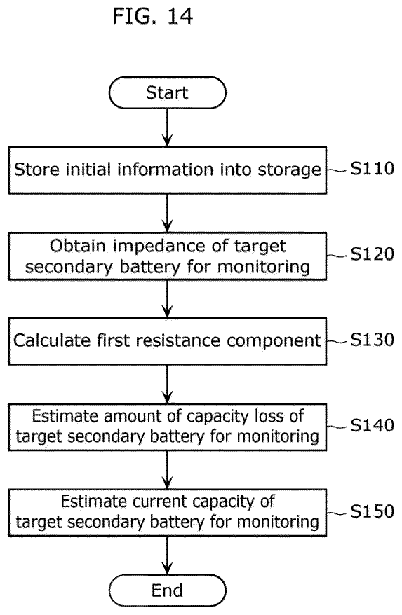

FIG. 14 shows an operation flow of battery monitoring device 1 according to Embodiment 1.

Battery monitoring device 1 stores initial information for monitoring secondary battery 5 into storage 24 (step S110). The initial information includes, for example, first relational expression E1 indicating the relationship between the amount of capacity loss of secondary battery 5 and a first resistance component that varies with the amount of capacity loss of secondary battery 5. First relational expression E1 may be represented by, for example, a linear equation, but is not limited thereto and may be represented by a gentle quadratic curve. Note that the initial information also includes values of wire-related resistance component I and resistance component II due to the electrolyte.

Next, battery monitoring device 1 obtains the impedance of target secondary battery 5 for monitoring (step S120).

Next, battery monitoring device 1 calculates the value of the first resistance component of target secondary battery 5 for monitoring (step S130). Specifically, battery monitoring device 1 calculates the value of resistance component III due to deposits of target secondary battery 5 for monitoring, based on the impedance obtained in step S120. The value of resistance component III due to deposits, that is, the first resistance component, is derived by the processes shown in FIG. 5 to FIG. 9.

Next, battery monitoring device 1 estimates the amount of capacity loss of target secondary battery 5 for monitoring, based on the value of the first resistance component obtained in step S130 and first relational expression E1 stored in storage 24 (step S140).

Next, battery monitoring device 1 estimates the current capacity of target secondary battery 5 for monitoring by subtracting the above amount of capacity loss from the initial capacity of secondary battery 5 (step S150).

By executing these steps, the reliability when monitoring the amount of capacity loss and the current capacity of secondary battery 5 can be enhanced.

### [Variation 1 of Embodiment 1]

Battery monitoring device 1 according to Variation 1 of Embodiment 1 will be described. In Variation 1, an example is described in which temperature correction is performed on resistance component III due to deposits, which is calculated by arithmetic processor 23.

Battery monitoring device 1 according to Variation 1 includes measurer-battery monitoring unit 8, controller 9, and communicator 10. Battery monitoring unit 8 includes arithmetic processor 23 and storage 24. The configurations of measurer 7, battery monitoring unit 8, controller 9, and communicator 10 in Variation 1 are the same as those in Embodiment 1.

In Variation 1, temperature corrector 23c of arithmetic processor 23 performs temperature correction on resistance component III due to deposits. Temperature correction is performed because the internal resistance of secondary battery 5 varies exponentially with temperature.

Temperature corrector 23c receives temperature information of secondary battery 5 measured by temperature measurer 15, and performs temperature correction on resistance component III due to deposits, based on the received temperature information.

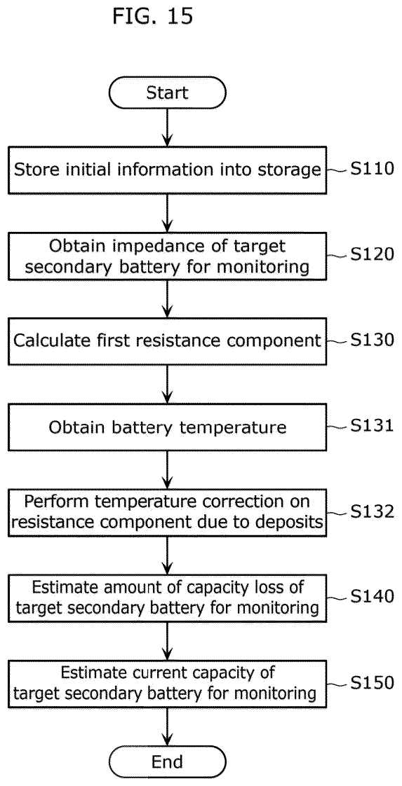

FIG. 15 shows an operation flow of battery monitoring device 1 according to Variation 1 of Embodiment 1.

The operation flow in Variation 1 is the same as that shown in FIG. 14 in Embodiment 1, except that steps S131 and S132 are added between steps S130 and S140. Note that added step S131 includes steps S210 to S240 in the following.

As shown in the figure, battery monitoring device 1 obtains the temperature of a target secondary battery for monitoring, after obtaining or immediately before obtaining resistance component III due to deposits (step S131 in FIG. 15). In Variation 1, battery monitoring device 1 executes the following processing to obtain the battery temperature.

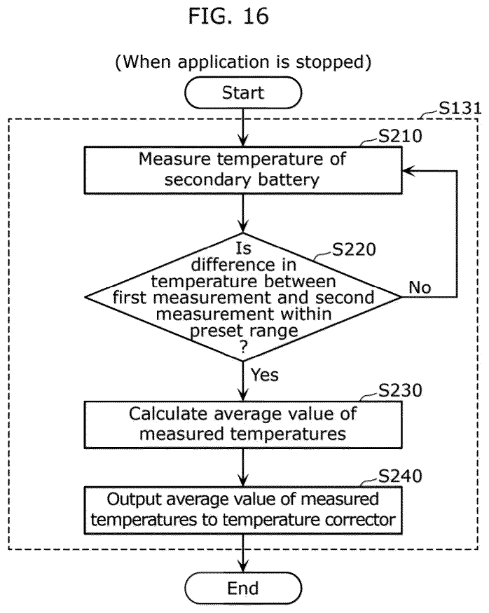

FIG. 16 shows a flow for obtaining the battery temperature.

Battery monitoring device 1 outputs, from controller 9, an instruction signal for measuring the temperature when an application is stopped. Based on this instruction signal, temperature measurer 15 measures the temperature of secondary battery 5 using thermistor 16 provided in an arbitrary location (step S210). For example, this temperature measurement is performed twice, and the first and second measurements are executed at a ten-minute interval according to a manufacturing preset value. Note that the number of measurements is not limited to two, and may be one or three or more.

Temperature measurer 15 determines whether the difference in temperature between the first measurement and the second measurement is within a predetermined range (step S220). When the temperature difference exceeds the preset range (No in S220), temperature measurer 15 returns to step S210 and measures the temperature of secondary battery 5 again.

On the other hand, when the temperature difference is within the preset range (Yes in S220), temperature measurer 15 calculates the average value of the first and second measured temperatures (step S230) and outputs the average value of the measured temperatures to temperature corrector 23c (step S240).

Temperature corrector 23c performs temperature correction on resistance component III due to deposits, based on the average value of the measured temperatures (step S132 in FIG. 15). For example, temperature corrector 23c performs temperature correction on resistance component III based on relational data between the battery temperature and resistance component III, which is stored in storage 24 in advance.

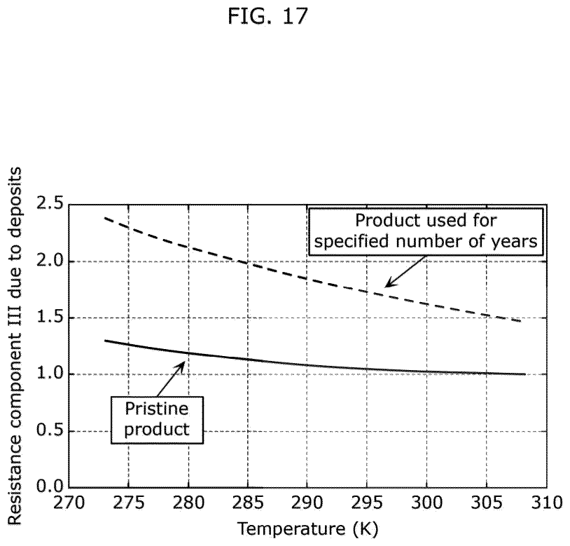

FIG. 17 shows relational data between resistance component III due to deposits and the battery temperature. Note that the figure also shows data for an initial product and for a product used for a specified number of years.

Temperature corrector 23c corrects the value of resistance component III due to deposits, based on relational data between resistance component III due to deposits and battery temperature, which is shown in FIG. 17. Temperature corrector 23c outputs the corrected value of resistance component III due to deposits to capacity loss estimator 23d.

Capacity loss estimator 23d estimates the amount of capacity loss of secondary battery 5, based on corrected resistance component III due to deposits (step S140).

Capacity loss estimator 23d outputs the amount of capacity loss resulting from the correction to SOH calculator 23e, for instance. SOH calculator 23e calculates the SOH, based on the amount of capacity loss resulting from the correction. Information on the SOH calculated by SOH calculator 23e is output to upper-level controller 2 via storage 24, controller 9, and communicator 10.

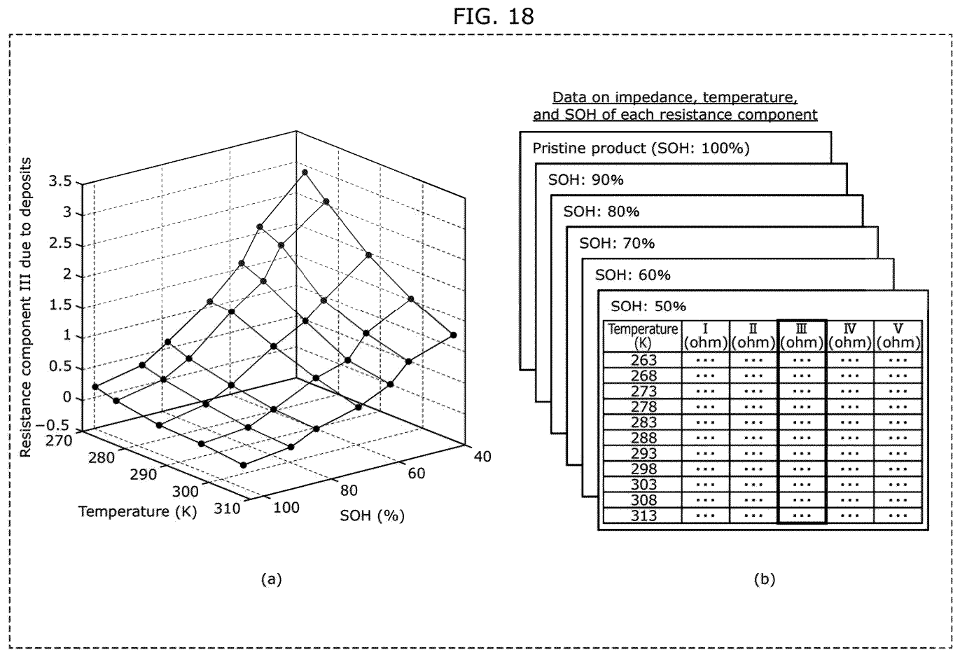

FIG. 18 shows the relationship among resistance component III due to deposits, the battery temperature, and the SOH. In FIG. 18, (a) shows a graph indicating the relationship among resistance component III due to deposits, the temperature, and the SOH, and (b) shows source data of (a).

The parameters in the figure are correlated, and may be managed in a map that consolidates correlational data. According to this, upper-level controller 2 can manage the power that can be charged and discharged, prevent overcharging and overdischarging of secondary battery 5, and can use secondary battery 5 efficiently for a long period.

### [Variation 2 of Embodiment 1]

Battery monitoring device 1A according to Variation 2 of Embodiment 1 will be described. In Variation 2, an example is described in which battery monitoring device 1A includes external storage device 25.

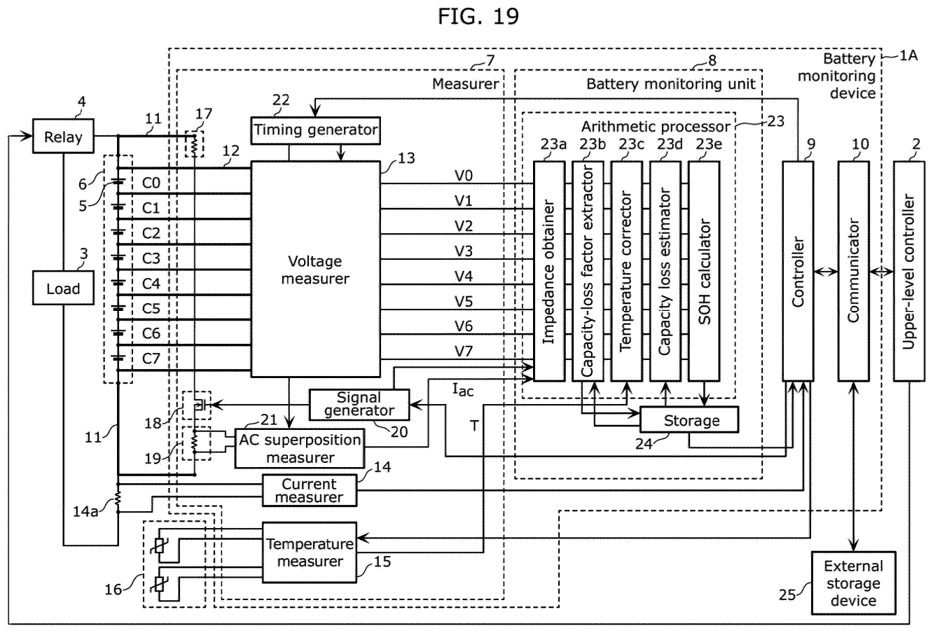

FIG. 19 is a block diagram showing battery monitoring device 1A according to Variation 2 of Embodiment 1.

Battery monitoring device 1A according to Variation 2 includes measurer 7, battery monitoring unit 8, controller 9, and communicator 10. Battery monitoring unit 8 includes arithmetic processor 23 and storage 24. The configurations of measurer 7, battery monitoring unit 8, controller 9, and communicator 10 in Variation 2 are the same as those in Embodiment 1.

As shown in the figure, battery monitoring device 1A according to Variation 2 includes external storage device 25. External storage device 25 is, for example, provided in a computer (server) connected via a network such as the Internet, or in a server in a cloud environment. In this case, battery monitoring device 1A downloads programs for estimating the state of secondary battery 5 over the network.

According to such battery monitoring device 1A, data stored in storage 24 of battery monitoring device 1A can be updated to data corresponding to the latest battery type, via external storage device 25. Accordingly, the battery state can be estimated highly accurately.

### [Variation 3 of Embodiment 1]

Battery monitoring device 1 according to Variation 3 of Embodiment 1 will be described. In Variation 3, a method for calculating a specific impedance component from impedance components in a pulsed current is described.

Battery monitoring device 1 according to Variation 3 includes measurer 7, battery monitoring unit 8, controller 9, and communicator 10. Battery monitoring unit 8 includes arithmetic processor 23 and storage 24.

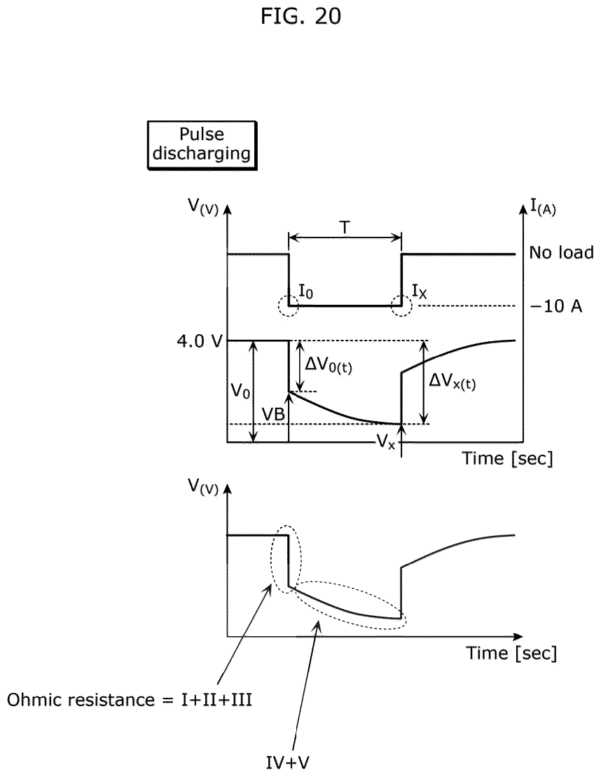

FIG. 20 shows another example when battery monitoring device 1 according to Variation 3 of Embodiment 1 measures the impedance of secondary battery 5.

FIG. 20 shows waveforms of the voltage and the current of secondary battery 5 during a discharge pulse of battery pack 6. In this example, differential voltage value ΔV₀ (=V₀−VB) between present OCV (voltage V₀) when secondary battery 5 is in an inactive state and voltage VB at the start of the charge/discharge interval is divided by current I₀ at the start of the charge/discharge interval, to calculate the ohmic resistance (=ΔV₀/I₀) of the equivalent circuit shown in FIG. 3. Resistance component III due to deposits can be obtained by removing, from the ohmic resistance, wire-related resistance component I and resistance component II due to the electrolyte. According to this calculation method, resistance component III due to deposits can be obtained without using a Nyquist plot.

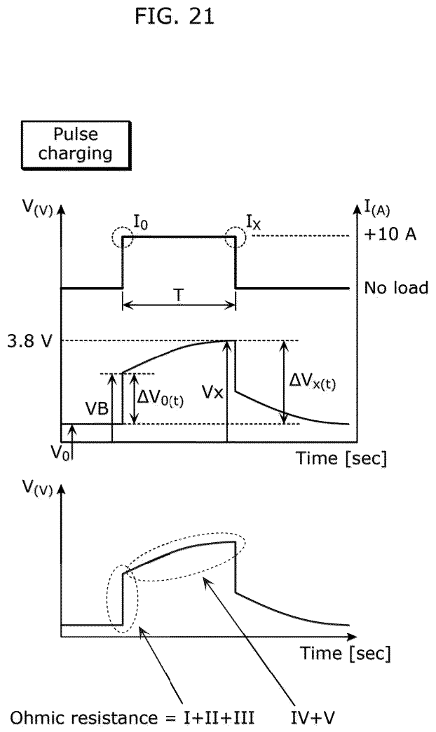

FIG. 21 shows yet another example when battery monitoring device 1 according to Variation 3 of Embodiment 1 measures the impedance of secondary battery 5.

FIG. 21 shows waveforms of the voltage and the current of secondary battery 5 during a charge pulse of battery pack 6. In this example, differential voltage value ΔV₀ (=VB−V₀) between present OCV (voltage V₀) when secondary battery 5 is in an inactive state and voltage VB at the start of the charge/discharge interval is divided by current I₀ at the start of the charge/discharge interval, to calculate the ohmic resistance (=ΔV₀/I₀) of the equivalent circuit shown in FIG. 3. Resistance component III due to deposits can be obtained by removing, from the ohmic resistance, wire-related resistance component I and resistance component II due to the electrolyte. According to this calculation method, resistance component III due to deposits can be obtained without using a Nyquist plot.

Note that in Variation 3, resistance component III is calculated by subtracting resistance components I and II from the ohmic resistance, which is the resistance from which resistance components IV and V are removed in advance, but nevertheless this calculation method is substantially the same as calculating resistance component III by subtracting resistance components I, II, IV, and V from the measured impedance of secondary battery 5.

### Embodiment 2

### [Circumstances Leading to the Present Disclosure]

In an Electric Vehicle (EV), battery (lithium-ion battery) performance is directly connected to vehicle performance such as travel distance. Generally, a battery has characteristics that battery life decreases faster in high-temperature environments and charging capability decreases in low-temperature environments. Thus, a battery cannot demonstrate optimal functionality unless the battery is in a suitable temperature environment.

Accordingly, battery temperature management becomes important, and battery operation is to be conducted within an appropriate temperature range. Furthermore, the battery state may be monitored, factors that could cause battery functional failure may be detected in advance, and warning messages, for instance, may be conveyed to an application user or to a controller.

For example, when the temperature decreases, battery impedance increases, and a lithium-ion battery may not be rapidly charged at a temperature below 0° C. On the other hand, thermal runaway may occur when the temperature rises to reach a range from 70° C. to 100° C., for example.

Furthermore, when batteries are used in EVs, the batteries are configured of a large number of series-connected batteries. Thus, measuring the temperatures of individual cells becomes complicated. Generally, the most degraded battery determines the capacity and current driving capability of the battery pack, but the most degraded battery may differ depending on a temperature. Thus, the temperatures of a large number of batteries are to be appropriately monitored.

The battery monitoring device according to Embodiment 2 has the following configuration to enhance reliability when monitoring the temperature of secondary battery 5.

### [Configuration of Battery Monitoring Device]

Battery monitoring device 1B according to Embodiment 2 will be described. In Embodiment 2, an example is described in which the temperature of secondary battery 5 is estimated using resistance component II due to the electrolyte. Note that hereinafter resistance component II due to the electrolyte may be referred to as a second resistance component. Resistance component II due to the electrolyte is an example of the second resistance component.

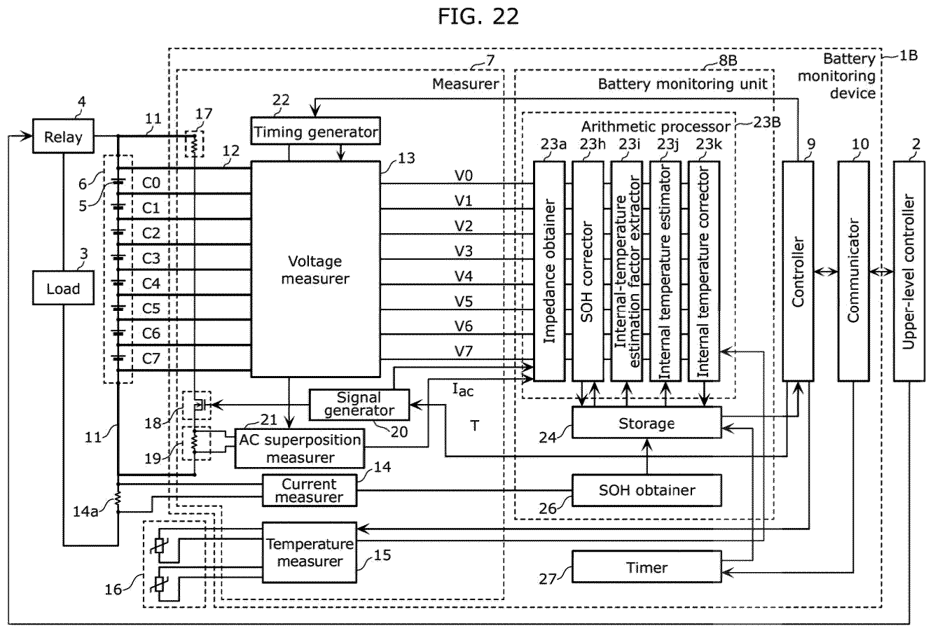

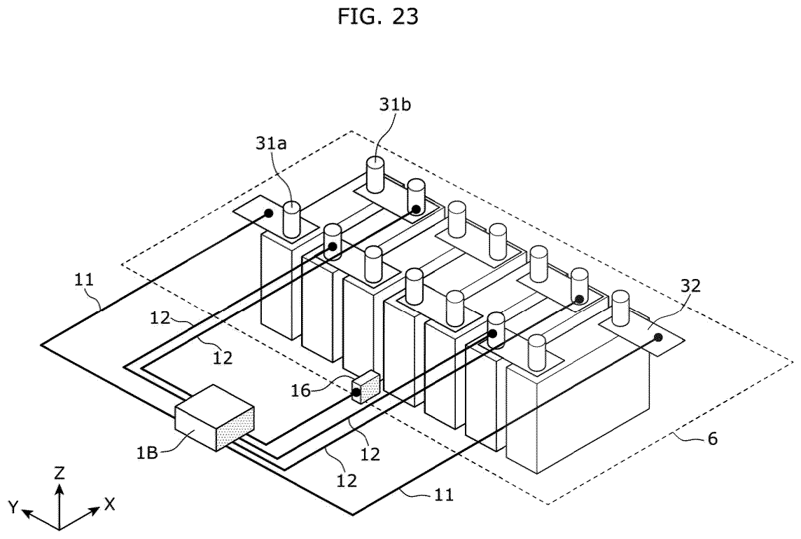

FIG. 22 is a schematic configuration diagram showing an example of battery monitoring device 1B according to Embodiment 2. FIG. 23 is a perspective view of battery monitoring device 1B according to Embodiment 2. Note that FIG. 22 also shows upper-level controller 2, load 3, and relay 4 in addition to battery monitoring device 1B. Furthermore, timer 27 is provided between storage 24 and communicator 10 in FIG. 22. The perspective view of battery monitoring device 1B is the same as that in Embodiment 1.

Battery monitoring device 1B is connected to battery pack 6 in which a plurality of secondary batteries 5 are combined and connected. Battery monitoring device 1B is a device that measures the internal impedances of secondary batteries 5 and monitors the states of secondary batteries 5.

As shown in FIG. 22, battery monitoring device 1B includes measurer 7, battery monitoring unit 8B, controller 9, and communicator 10. The configurations of measurer 7, controller 9, and communicator 10 are the same as those in Embodiment 1.

Battery monitoring unit 8B shown in FIG. 22 is a BMU and includes arithmetic processor 23B and storage 24. Furthermore, battery monitoring unit 8B according to Embodiment 2 includes SOH obtainer 26.

Storage 24 stores in advance relational data indicating the relationship between the state of secondary battery 5 and a resistance component that varies with the state of secondary battery 5. For example, storage 24 stores a relational expression similar to first relational expression E1 shown in Embodiment 1 and second relational expression E2 described later. Storage 24 also stores the value of wire-related resistance component I. Note that first relational expression E1 and second relational expression E2 are examples of relational data.

First relational expression E1 indicates the relationship between the amount of capacity loss of secondary battery 5 and a first resistance component that varies with the amount of capacity loss of secondary battery 5. In this example, the first resistance component is resistance component III due to deposits that are deposited on the surface of the negative electrode of secondary battery 5.

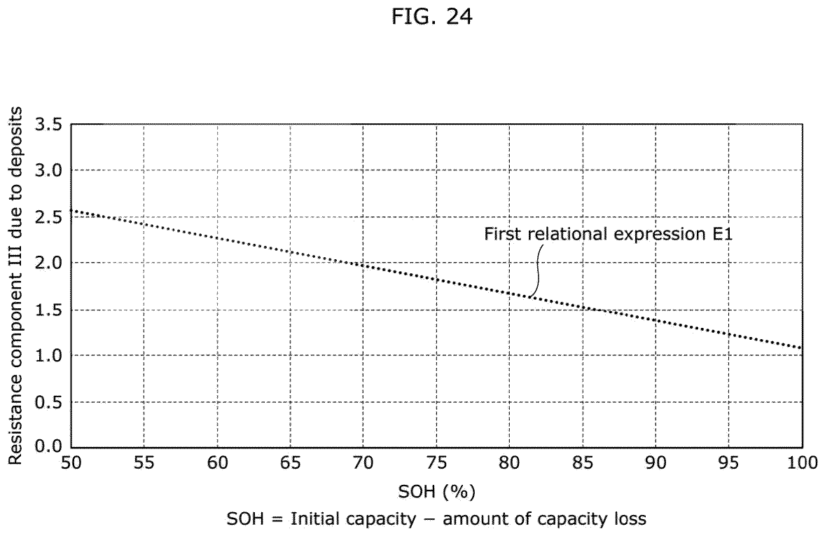

FIG. 24 shows relational data between resistance component III due to deposits and the SOH.

In the figure, the vertical axis represents resistance component III due to deposits, and the horizontal axis represents the SOH (%). The horizontal axis in the figure represents the SOH, but this is because the amount of capacity loss represented by the horizontal axis in FIG. 11 is replaced with the SOH, based on “SOH=(initial capacity)−(amount of capacity loss)” in Expression 5. Thus, the relational data shown in FIG. 24 is substantially the same as first relational expression E1. In the present embodiment, the relationship between resistance component III due to deposits and the SOH shown in FIG. 24 is also described as having the relationship according to first relational expression E1.

Second relational expression E2 indicates the relationship between the internal temperature of secondary battery 5 and a second resistance component that varies with the internal temperature of secondary battery 5. In this example, the second resistance component is the resistance component based on the migration resistance in the electrolyte of secondary battery 5, namely, resistance component II due to the electrolyte.

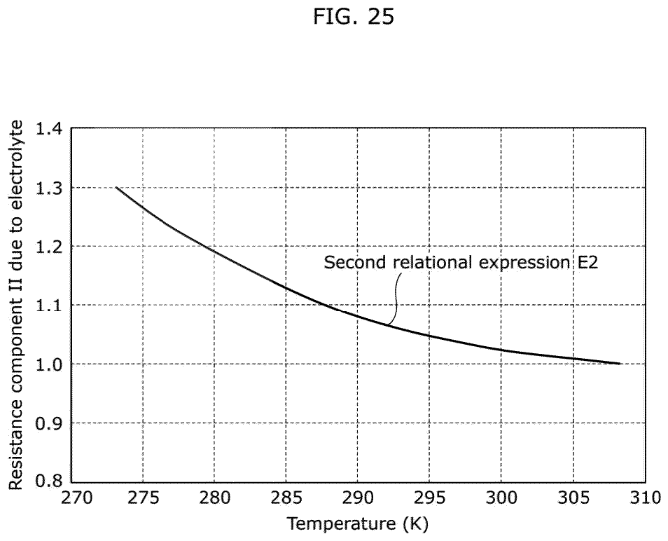

FIG. 25 shows relational data between resistance component II due to the electrolyte and the battery temperature.

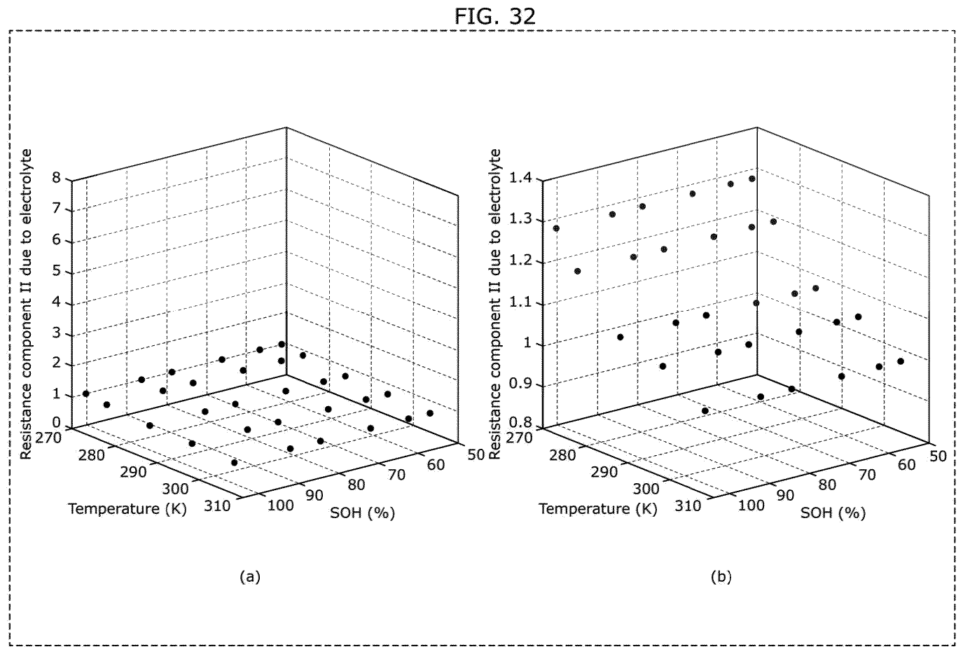

In the figure, the horizontal axis represents the battery temperature and the vertical axis represents resistance component II due to the electrolyte. As shown in the figure, the battery temperature and resistance component II due to the electrolyte are correlated. The relationship between the battery temperature and resistance component II due to the electrolyte is expressed by curve-approximated second relational expression E2. Second relational expression E2 shown in the figure is obtained by data collection in advance, and stored into storage 24. Note that the relationship between the battery temperature and resistance component II due to the electrolyte is a relationship that does not depend on changes in the SOH (refer to FIG. 32). Accordingly, it is possible to estimate the battery temperature using resistance component II due to the electrolyte.

Arithmetic processor 23B calculates a value of a resistance component that varies according to the state of target secondary battery 5 for monitoring, based on the impedance obtained through the measurement by measurer 7, and estimates the state of secondary battery 5, based on the value of the resistance component and the relational data stored in storage 24.

To perform the above processing, arithmetic processor 23B includes impedance obtainer 23a, SOH corrector 23h, internal-temperature estimation factor extractor 23i, internal temperature estimator 23j, and internal temperature corrector 23k.

Such impedance obtainer 23a, SOH corrector 23h, internal-temperature estimation factor extractor 23i, internal temperature estimator 23j, and internal temperature corrector 23k constitute a functional configuration for estimating internal temperatures of batteries C0 to C7, for instance.

Impedance obtainer 23a obtains impedances Z0 to Z7 of batteries C0 to C7, based on voltages V0 to V7 of batteries C0 to C7 measured by voltage measurer 13 and current value Iac measured and converted into voltage by AC superposition measurer 21. Impedances Z0 to Z7 are complex numbers, and real part ReZ and imaginary part ImZ are calculated for each of batteries C0 to C7. A calculated complex impedance is a ratio, at each frequency, of the voltage measured by voltage measurer 13 to the current measured by AC superposition measurer 21 when signal generator 20 outputs an AC current from battery pack 6 at the frequency. Impedance obtainer 23a outputs calculated complex impedance values Z0 to Z7 of batteries C0 to C7 to internal-temperature estimation factor extractor 23i.

As described above, battery monitoring unit 8B includes SOH obtainer 26. SOH obtainer 26 computes and obtains the SOH based on the integrated amount of currents measured by current measurer 14, and outputs the obtained SOH to SOH corrector 23h via storage 24. SOH corrector 23h outputs the obtained SOH to the internal-temperature estimation factor extractor 23i.

Internal-temperature estimation factor extractor 23i extracts resistance component II due to the electrolyte of secondary battery 5 by performing predetermined processing using complex impedance values Z0 to Z7 output from impedance obtainer 23a and the SOH output from SOH corrector 23h.

Arithmetic processor 23B performs the following processing to estimate the internal temperature of secondary battery 5 using resistance component II due to the electrolyte, which is the second resistance component.

For example, internal-temperature estimation factor extractor 23i calculates the value of the first resistance component of target secondary battery 5 for monitoring, based on the SOH obtained by SOH obtainer 26 and first relational expression E1 stored in storage 24, and obtains the value of the second resistance component based on that value of the first resistance component. Internal-temperature estimator 23j estimates the internal temperature of secondary battery 5, based on the value of the second resistance component and second relational expression E2.

Note that the first resistance component is resistance component III due to deposits and is derived from first relational expression E1 shown in FIG. 24. In other words, the first resistance component is computed and obtained by SOH obtainer 26 and is derived by applying the SOH output from SOH corrector 23h to first relational expression E1.

When calculating the value of the second resistance component, internal-temperature estimation factor extractor 23i calculates the value of the second resistance component by removing, from the impedance obtained by impedance obtainer 23a, wire-related resistance component I determined by the resistance component of the wire connected to secondary battery 5 and the resistance component between the wire and secondary battery 5; resistance component III due to deposits, which is the first resistance component; and negative-electrode resistance component IV and positive-electrode resistance component V of secondary battery 5.

A Nyquist plot as described above is used to calculate the value of the second resistance component. Note that the Nyquist plot of secondary battery 5, the figure showing wire-related resistance component I, and the figure showing the state in which wire-related resistance component I is removed from the plurality of resistance components of secondary battery 5 correspond to FIG. 5, FIG. 6, and FIG. 7, respectively, and thus the following description proceeds from those points.

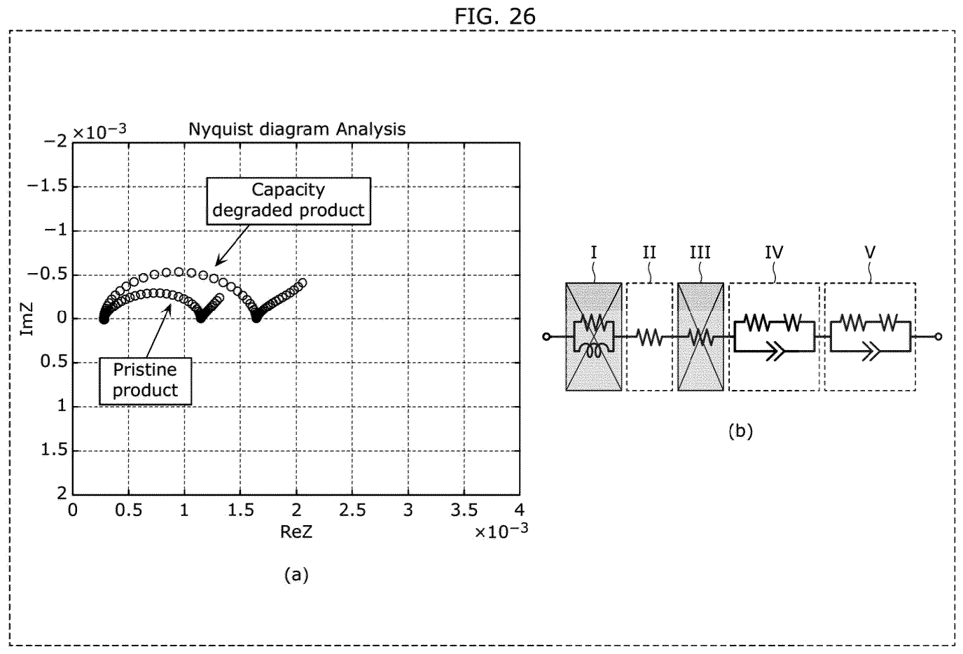

FIG. 26 shows the state in which wire-related resistance component I and resistance component III due to deposits are removed from the plurality of resistance components of each secondary battery 5. Part (a) of FIG. 26 shows a Nyquist plot showing changes in impedance of resistance component II due to the electrolyte, negative-electrode resistance component IV, and positive-electrode resistance component V. Part (b) of FIG. 26 shows an equivalent circuit of resistance component II due to the electrolyte, negative-electrode resistance component IV, and positive-electrode resistance component V.

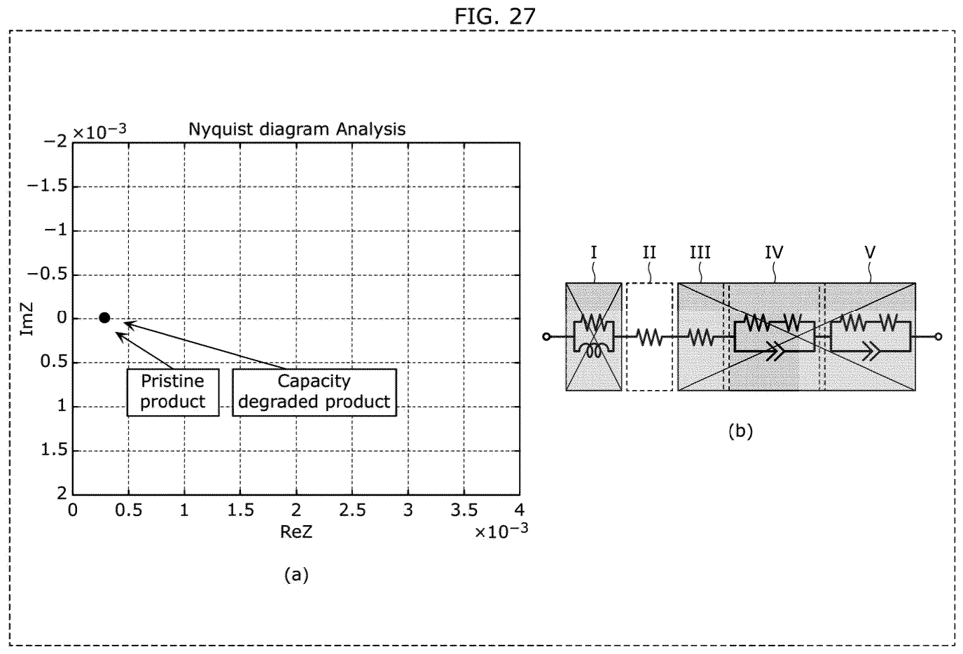

FIG. 27 shows the state in which wire-related resistance component I, resistance component III due to deposits, negative-electrode resistance component IV, and positive-electrode resistance component V are removed from the plurality of resistance components of each secondary battery 5, and resistance component II due to the electrolyte is extracted. Part (a) of FIG. 27 shows a Nyquist plot showing changes in impedance of resistance component II due to the electrolyte. As shown in the figure, the value of resistance component II due to the electrolyte is represented by only the real part of complex impedance Z. Part (b) of FIG. 27 shows an equivalent circuit of resistance component II due to the electrolyte.

Note that wire-related resistance component I is a value obtained according to Embodiment 1 and is stored in advance in storage 24. Resistance component III due to deposits, which is the first resistance component, is derived from the SOH output by SOH corrector 23h and first relational expression E1 shown in FIG. 24. Negative-electrode resistance component IV and positive-electrode resistance component V are values obtained by curve-fitting the Nyquist plot that represents changes in impedance of secondary battery 5.

Note that resistance component II due to the electrolyte may be calculated from the impedance components in a pulse current, as shown in FIG. 20 and FIG. 21.

As described above, resistance component II due to the electrolyte is extracted from the impedance of secondary battery 5 by removing wire-related resistance component I, resistance component III due to deposits, negative-electrode resistance component IV, and positive-electrode resistance component V.

Information on the second resistance component (resistance component II due to the electrolyte) extracted by internal-temperature estimation factor extractor 23i is output to internal temperature estimator 23j.

Internal temperature estimator 23j estimates the internal temperature of secondary battery 5, based on the value of the second resistance component and second relational expression E2 stored in storage 24. Specifically, internal temperature estimator 23j derives the internal temperature of secondary battery 5 by substituting the value of the second resistance component into second relational expression E2.

Information on the internal temperature of secondary battery 5 obtained by internal temperature estimator 23j is notified to upper-level controller 2 via storage 24, controller 9, and communicator 10. Communicator 10 is a communication module and transmits the above information to upper-level controller 2 in a wireless or wired manner. Upper-level controller 2 executes control corresponding to the notified internal temperature of secondary battery 5 in a vehicle.

Battery monitoring device 1B according to the present embodiment calculates the value of resistance component II due to the electrolyte, based on the impedance obtained by impedance obtainer 23a. Then, the state of secondary battery 5 is estimated based on the value of resistance component II due to the electrolyte and second relational expression E2. As described above, the reliability when monitoring the state of secondary battery 5 can be enhanced by monitoring the state of secondary battery 5 based on, 15 for instance, reliable data.

### [Operation of Battery Monitoring Device]

The operation of battery monitoring device 1B according to Embodiment 2 will be described.

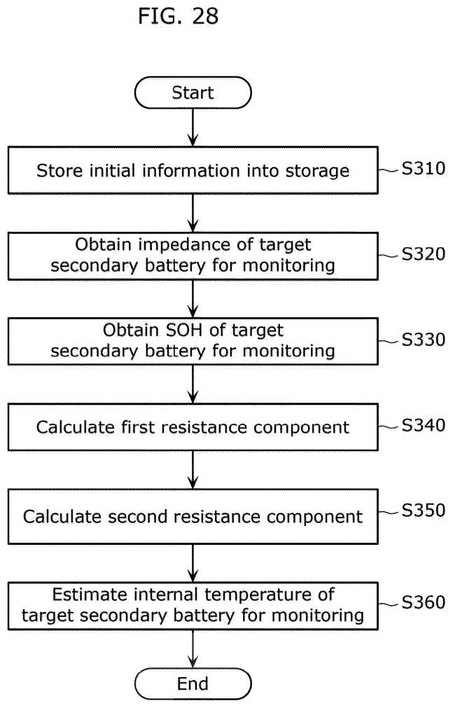

FIG. 28 shows an operation flow of battery monitoring device 1B according to Embodiment 2.

Battery monitoring device 1B stores initial information for monitoring secondary battery 5 into storage 24 (step S310). The initial information includes, for example, second relational expression E2 indicating the relationship between the internal temperature of secondary battery 5 and a second resistance component that varies with the internal temperature of secondary battery 5. The initial information also includes first relational expression E1 indicating the relationship between the amount of capacity loss of secondary battery 5 and a first resistance component that varies with the amount of capacity loss of secondary battery 5. Note that the horizontal axis of first relational expression E1 may represent the amount of capacity loss as described above, or may represent the SOH (%). The initial information further includes the value of wire-related resistance component I.

Next, battery monitoring device 1B obtains the impedance of target secondary battery 5 for monitoring (step S320).

Next, battery monitoring device 1B obtains the SOH of the target secondary battery for monitoring (step S330). For example, SOH obtainer 26 obtains the SOH by performing cumulative computation on data measured by current measurer 14.

Next, battery monitoring device 1B calculates the value of the first resistance component (resistance component III due to deposits) of target secondary battery 5 for monitoring (step S340). Specifically, battery monitoring device 1B derives the value of resistance component III due to deposits of secondary battery 5, based on the SOH obtained in step S330 and first relational expression E1 stored in storage 24. Note that steps S320 and S330 may be executed between step S310 and step S320, or may be executed simultaneously with step S320.

Next, battery monitoring device 1B calculates the value of resistance component II due to the electrolyte, which is the second resistance component, based on the value of resistance component III due to deposits (step S350). For example, battery monitoring device 1B calculates the value of the second resistance component by removing, from the impedance obtained in step S320, wire-related resistance component I, resistance component III due to deposits that is the first resistance component, and negative-electrode resistance component IV and positive-electrode resistance component V.

Next, battery monitoring device 1B obtains the internal temperature of target secondary battery 5 for monitoring, based on the second resistance component obtained in step S350 and second relational expression E2 stored in storage 24 (step S360).

By executing these steps, the reliability when monitoring the internal temperature of secondary battery 5 can be enhanced.

### [Variation 1 of Embodiment 2]

Battery monitoring device 1B according to Variation 1 of Embodiment 2 will be described. In Variation 1, an example is described in which the internal temperature estimated by arithmetic processor 23 is corrected.

Battery monitoring device 1B in this example includes measurer 7, battery monitoring unit 8B, controller 9, and communicator 10. Battery monitoring unit 8B includes arithmetic processor 23B and storage 24. The configurations of measurer 7, battery monitoring unit 8B, controller 9, and communicator 10 in this example are the same as those in Embodiment 2.

Internal temperature corrector 23k of arithmetic processor 23B corrects the estimated value of the internal temperature of secondary battery 5, based on the external temperature measured by temperature measurer 15.

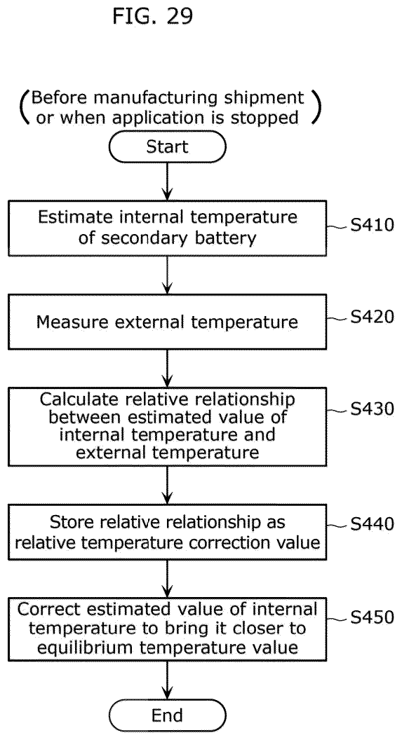

FIG. 29 shows the method of correcting the estimated value of the internal temperature of secondary battery 5, which is performed in Variation 1 of Embodiment 2.

For example, second relational equation E2 indicating the relationship between resistance component II due to the electrolyte and the battery temperature may be prepared for each individual battery, but nevertheless, a statistical average value of a certain population is adopted in practice. In view of this, the correlation between the internal temperature calculated from the measured impedance and the external temperature measured by temperature measurer 15 is obtained, and a temperature correction is applied based on the temperature when battery pack 6 reaches thermal equilibrium.

First, battery monitoring device 1B estimates the internal temperature before manufacturing shipment, possibly in an environment adjusted to a temperature of at least 15° C. and at most 30° C. (step S410).

Furthermore, battery monitoring device 1B measures the external temperature (step S420).

Next, battery monitoring device 1B calculates the relative relationship between the estimated value of the internal temperature and the external temperature (step S430).

Battery monitoring device 1B stores the relative relationship calculated in step S430 into storage 24, as a relative temperature correction value (step S440).

Internal temperature corrector 23k of battery monitoring device 1B corrects the estimated value of the internal temperature to bring it closer to the equilibrium temperature value of battery pack 6, by using the relative relationship value stored in storage 24 (step S450).

Battery monitoring device 1B outputs information on the corrected battery temperature, the resistance components included in the impedance of each secondary battery 5, and information on the SOH, for instance, to upper-level controller 2 via storage 24, controller 9, and communicator 10.

In the following, an example of information on each resistance component, the battery temperature, and the SOH is shown.

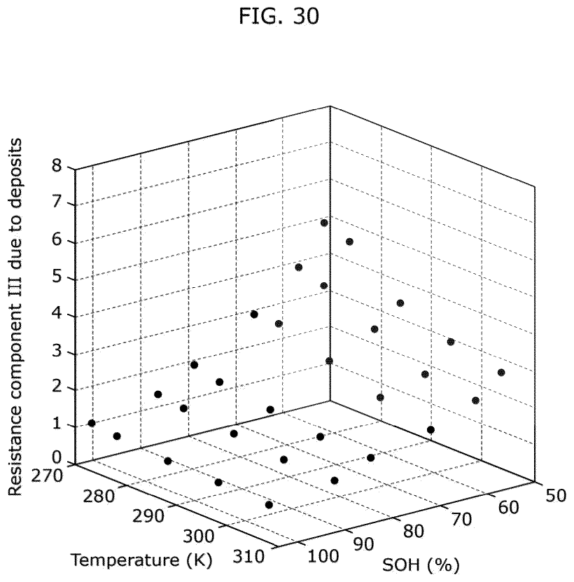

FIG. 30 shows the relationship among resistance component III due to deposits, the battery temperature, and the SOH.

As shown in FIG. 30, the relationship between resistance component III due to deposits and the battery temperature exhibits entirely different tendencies when the SOH changes. Thus, it is not easy to use resistance component III due to deposits when the battery temperature is estimated.

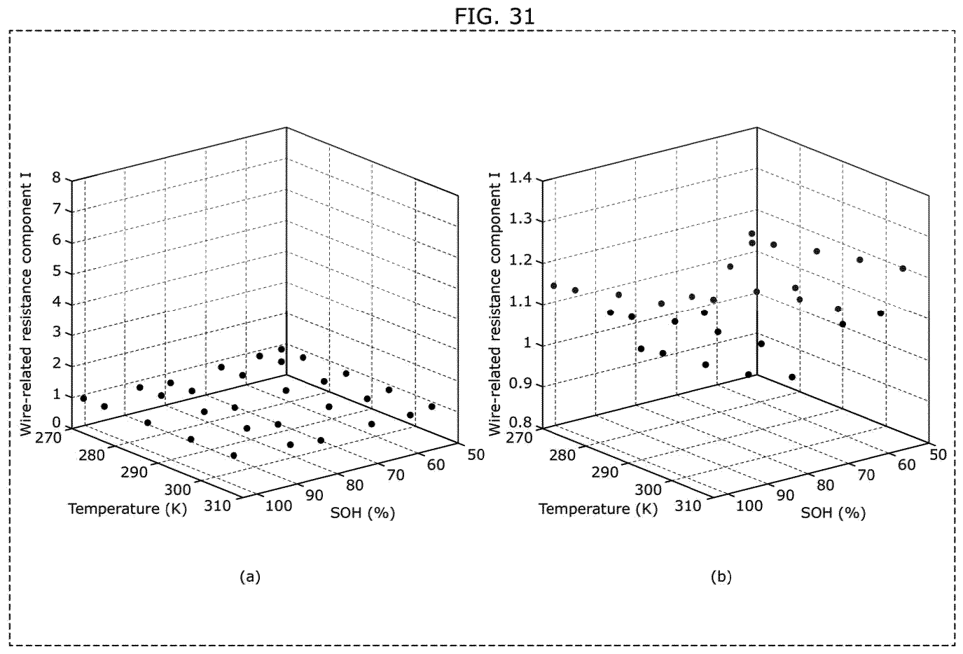

FIG. 31 shows the relationship among wire-related resistance component I, the battery temperature, and the SOH. Parts (a) and (b) of FIG. 31 show figures with different vertical-axis scales.

As shown in FIG. 31, the relationship between wire-related resistance component I and the battery temperature shows different tendencies when the SOH changes. Thus, it is difficult to use wire-related resistance component I when the battery temperature is to be estimated.

FIG. 32 shows the relationship among resistance component II due to the electrolyte, the battery temperature, and the SOH. Parts (a) and (b) of FIG. 32 show figures with different vertical-axis scales.

As shown in FIG. 32, the relationship between resistance component II due to the electrolyte and the battery temperature shows the same tendency even when the SOH changes, and thus is a relationship that does not depend on the SOH. Thus, the battery temperature can be readily estimated by using resistance component II due to the electrolyte when the battery temperature is to be estimated.

The parameters shown in FIG. 32 may be managed in a map. According to this, upper-level controller 2 can manage temperatures of secondary batteries 5, for instance, prevent overcharging and overdischarging of secondary batteries 5, and can use secondary batteries 5 efficiently for a long period.

### [Variation 2 of Embodiment 2]

Battery monitoring device 1C according to Variation 2 of Embodiment 2 will be described. In Variation 2, an example is described in which battery monitoring device 1C includes external storage device 25.

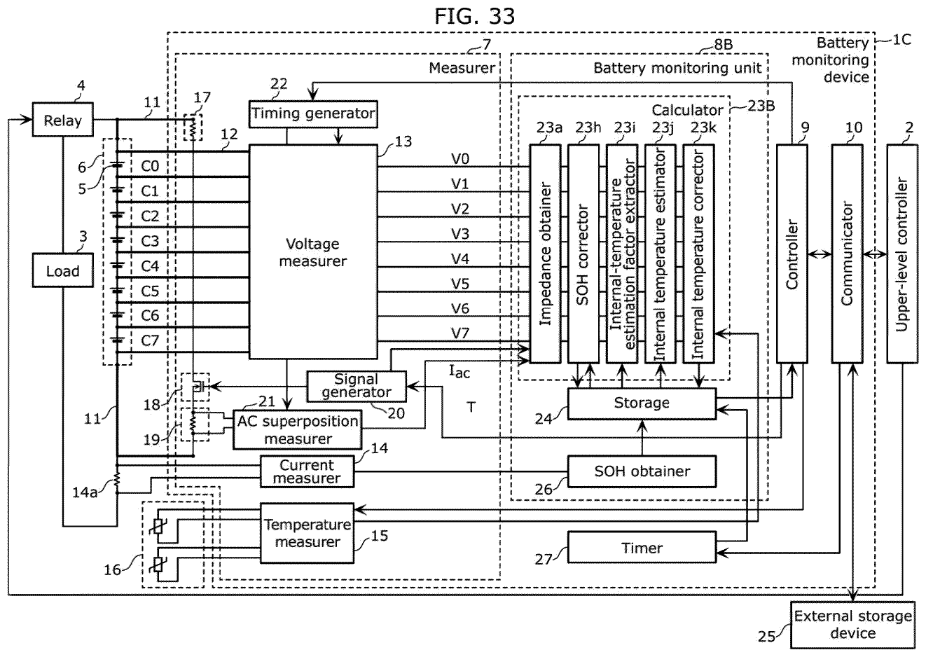

FIG. 33 is a block diagram showing battery monitoring device 1C according to Variation 2 of Embodiment 2.

Battery monitoring device 1C according to Variation 2 includes measurer 7, battery monitoring unit 8B, controller 9, and communicator 10. Battery monitoring unit 8B includes arithmetic processor 23 and storage 24. The configurations of measurer 7, battery monitoring unit 8B, controller 9, and communicator 10 in Variation 2 are the same as those in Embodiment 2.

As shown in the figure, battery monitoring device 1C according to Variation 2 includes external storage device 25. External storage device 25 is, for example, provided in a computer (server) connected via a network such as the Internet, or in a server in a cloud environment. In this case, battery monitoring device 1C downloads programs for estimating the state of secondary battery 5 over the network.

According to such battery monitoring device 1C, the data stored in storage 24 of battery monitoring device 1C can be updated to data corresponding to the latest battery type, via external storage device 25. Accordingly, the battery state can be estimated highly accurately.

### (Summary of Embodiments 1 and 2)

Examples of the battery monitoring devices according to Embodiments 1 and 2 are shown.

A battery monitoring device according to Example 1 includes: storage 24 that stores relational data indicating, for each of plural secondary batteries 5, a relationship between a state of secondary battery 5 and a resistance component that varies with the state of secondary battery 5, among a plurality of resistance components included in an impedance of secondary battery 5; impedance obtainer 23a that obtains an impedance of target secondary battery 5 for monitoring, among plural secondary batteries 5; and arithmetic processer 23 that calculates, based on the impedance obtained by impedance obtainer 23a, a value of a resistance component that varies with a state of target secondary battery 5 for monitoring, and estimates the state of target secondary battery 5 for monitoring, based on the value of the resistance component calculated and the relational data.

As described above, the state of secondary battery 5 can be monitored based on reliable data, for instance, by estimating the state of secondary battery 5 based on the value of the resistance component that varies with the battery state and the relational data described above. Accordingly, reliability when monitoring the states of secondary batteries 5 can be enhanced.

Battery monitoring device 1 according to Example 2 is the battery monitoring device according to Example 1 in which storage 24 stores, as the relational data, first relational expression E1 indicating, for each of the plurality of secondary batteries, a relationship between an amount of capacity loss of secondary battery 5 and a first resistance component that varies with the amount of capacity loss of secondary battery 5. Arithmetic processer 23 may calculate a value of the first resistance component of target secondary battery 5 for monitoring, based on the impedance obtained by impedance obtainer 23a, and estimate an amount of capacity loss of target secondary battery 5 for monitoring, based on the value of the first resistance component calculated and first relational expression E1.

As described above, the amount of capacity loss of secondary battery 5 can be monitored based on reliable data, for instance, by estimating the amount of capacity loss of secondary battery 5, based on the value of the first resistance component that varies with the battery state and first relational expression E1. Accordingly, reliability when monitoring the states of secondary batteries 5 can be enhanced.

Battery monitoring device 1 according to Example 3 is the battery monitoring device according to Example 2 in which first relational expression E1 may be derived based on the amounts of capacity loss of secondary batteries 5 whose capacities are equal to or less than a capacity of a pristine product, and on first resistance components obtained by measuring impedances of secondary batteries 5.

As described above, the reliability of first relational expression E1 can be enhanced by deriving first relational expression E1 based on empirical data. Thus, the amount of capacity loss of secondary battery 5 can be monitored based on reliable data, for instance. Accordingly, reliability when monitoring the states of secondary batteries 5 can be enhanced.

Battery monitoring device 1 according to Example 4 is the battery monitoring device according to Example 2 or 3 in which the amount of capacity loss of secondary battery 5 in first relational expression E1 may be calculated based on the amount of irreversible lithium remaining on the negative electrode of secondary battery 5.

Thus, the reliability of first relational expression E1 can be enhanced by calculating the amount of capacity loss based on the amount of irreversible lithium. Thus, the amount of capacity loss of secondary battery 5 can be monitored based on reliable data, for instance. Accordingly, reliability when monitoring the states of secondary batteries 5 can be enhanced.

Battery monitoring device 1 according to Example 5 is the battery monitoring device according to any one of Examples 2 to 4 in which the first resistance component in first relational expression E1 may be obtained by removing, from the impedance of secondary battery 5 whose capacity is less than or equal to the capacity of a pristine product: resistance component I determined by a resistance component of a wire connected to secondary battery 5 and a resistance component between the wire and secondary battery 5; resistance component II based on migration resistance in the electrolyte of secondary battery 5; and negative-electrode resistance component IV and positive-electrode resistance component V of secondary battery 5.

The reliability of first relational expression E1 can be enhanced by obtaining the first resistance component as described above. Thus, the amount of capacity loss of secondary battery 5 can be monitored based on reliable data, for instance. Accordingly, reliability when monitoring the states of secondary batteries 5 can be enhanced.

Battery monitoring device 1 according to Example 6 is the battery monitoring device according to any one of Examples 2 to 5 in which arithmetic processor 23 may calculate the value of the first resistance component by removing, from the impedance obtained by impedance obtainer 23a, resistance component I determined by the resistance of a wire connected to target secondary battery 5 for monitoring and the resistance between the wire and the secondary battery, resistance component II based on the migration resistance in the electrolyte of target secondary battery 5 for monitoring, and negative-electrode resistance component IV and positive-electrode resistance component V of target secondary battery 5 for monitoring.

According to this, a highly reliable first resistance component can be obtained by computation. Accordingly, reliability when monitoring the states of secondary batteries 5 can be enhanced.

Battery monitoring device 1 according to Example 7 is the battery monitoring device according to any one of Examples 2 to 6 in which the first resistance component may be resistance component III due to deposits that accumulate on the surface of the negative electrode of secondary battery 5.

According to this, the first resistance component can be obtained by computation. Accordingly, reliability when monitoring the states of secondary batteries 5 can be enhanced.

Battery monitoring device 1 according to Example 8 is the battery monitoring device according to any one of Examples 2 to 7 in which arithmetic processor 23 may estimate the current capacity of target secondary battery 5 for monitoring by subtracting the amount of capacity loss estimated by arithmetic processor 23 from the initial capacity of target secondary battery 5 for monitoring.

According to this, the current capacity of secondary battery 5 can be estimated based on a reliable amount of capacity loss. Accordingly, reliability when monitoring the states of secondary batteries 5 can be enhanced.

Battery monitoring device 1B according to Example 9 is the battery monitoring device according to Example 1 in which storage 24 stores, as the relational data, second relational expression E2 indicating, for each of plural secondary batteries 5, a relationship between an internal temperature of secondary battery 5 and a second resistance component that varies with the internal temperature of secondary battery 5. Arithmetic processer 23B may calculate a value of the second resistance component of target secondary battery 5 for monitoring, based on the impedance obtained by impedance obtainer 23a, and estimate an internal temperature of target secondary battery 5 for monitoring, based on the value of the second resistance component calculated and second relational expression E2.

As described above, the internal capacity of secondary battery 5 can be monitored based on reliable data, for instance, by estimating the internal temperature of secondary battery 5, based on the value of the second resistance component that varies with the battery state and second relational expression E2. Accordingly, reliability when monitoring the states of secondary batteries 5 can be enhanced.

Battery monitoring device 1B according to Example 10 is the battery monitoring device according to Example 9 and further includes SOH obtainer 26 that obtains the SOH of target secondary battery 5 for monitoring. Storage 24 further stores first relational expression E1 indicating the relationship between the amount of capacity loss of secondary battery 5 and a first resistance component that varies with the amount of capacity loss of secondary battery 5. Arithmetic processor 23B may calculate the value of the first resistance component of target secondary battery 5 for monitoring based on the SOH obtained by SOH obtainer 26 and first relational expression E1, and may obtain the value of the second resistance component based on the value of the first resistance component calculated.

Thus, the reliability of the value of the second resistance component can be enhanced by obtaining the first resistance component based on the SOH and first relational expression E1, and further obtaining the second resistance component based on that first resistance component. Hence, the internal temperature of secondary battery 5 can be estimated based on a reliable value. Accordingly, reliability when monitoring the states of secondary batteries 5 can be enhanced.

Battery monitoring device 1B according to Example 11 is the battery monitoring device according to Example 10 in which arithmetic processor 23B may calculate the value of the second resistance component by removing, from the impedance obtained by impedance obtainer 23a, resistance component I determined by the resistance of a wire connected to target secondary battery 5 for monitoring and the resistance between the wire and target secondary battery 5 for monitoring, the first resistance component, and negative-electrode resistance component IV and positive-electrode resistance component V of target secondary battery 5 for monitoring.

A highly reliable second resistance component can be obtained by computation by calculating the value of the second resistance component as described above. Accordingly, reliability when monitoring the states of secondary batteries 5 can be enhanced.

Battery monitoring device 1B according to Example 12 is the battery monitoring device according to any one of Examples 9 to 11 in which the second resistance component may be resistance component II based on migration resistance in the electrolyte of secondary battery 5.

According to this, the second resistance component can be obtained by computation. Accordingly, reliability when monitoring the states of secondary batteries 5 can be enhanced.

A battery monitoring device according to Example 13 is the battery monitoring device according to any one of Examples 1 to 12 and further includes temperature measurer 15 that measures the external temperature of target secondary battery 5 for monitoring, and temperature corrector 23c that corrects a resistance component that varies with a battery state, based on the external temperature. Arithmetic processor 23 may estimate the state of target secondary battery 5 for monitoring, based on the resistance component after correction by temperature corrector 23c.

According to this, the above resistance component can be obtained based on the external temperature. Accordingly, reliability when monitoring the states of secondary batteries 5 can be enhanced.

A battery monitoring device according to Example 14 is the battery monitoring device according to any one of Examples 1 to 12, and may further include communicator 10 that transmits data stored in storage 24 to an external device

According to this, upper-level controller 2 can manage temperatures of secondary batteries 5, for instance, prevent overcharging and overdischarging of secondary batteries 5, and can use secondary batteries 5 efficiently for a long period.

A battery monitoring method according to Example 15 includes: obtaining relational data indicating a relationship between a state of secondary battery 5 and a resistance component that varies with the state of secondary battery 5, among a plurality of resistance components included in an impedance of secondary battery 5; obtaining impedance of target secondary battery 5 for monitoring; and calculating a value of a resistance component that varies with a state of target secondary battery 5 for monitoring based on the impedance obtained, and estimating a state of target secondary battery 5 for monitoring based on a value of the resistance component calculated and the relational data.

As described above, the state of secondary battery 5 can be monitored based on reliable data, for instance, by estimating the state of secondary battery 5 based on the value of the resistance component that varies with the battery state and the relational data described above. Accordingly, reliability when monitoring the states of secondary batteries 5 can be enhanced.

A battery monitoring method according to Example 16 is the battery monitoring method according to Example 15 in which in the obtaining of the relational data, first relational expression E1 indicating the relationship between the amount of capacity loss of secondary battery 5 and a first resistance component that varies with the amount of capacity loss of secondary battery 5 may be obtained as the relational data; and in the calculating, the value of the first resistance component of target secondary battery 5 for monitoring may be calculated based on the impedance obtained, and the amount of capacity loss of target secondary battery 5 for monitoring may be estimated based on the first resistance component value calculated and first relational expression E1.

As described above, the amount of capacity loss of secondary battery 5 can be monitored based on reliable data, for instance, by estimating the amount of capacity loss of secondary battery 5, based on the value of the first resistance component that varies with the battery state and first relational expression E1. Accordingly, reliability when monitoring the states of secondary batteries 5 can be enhanced.

A battery monitoring method according to Example 17 is the battery monitoring method according to Example 15 in which in the obtaining of the relational data, second relational expression E2 indicating a relationship between the internal temperature of secondary battery 5 and a second resistance component that varies with the internal temperature of secondary battery 5 may be obtained as the relational data; and in the calculating, the value of the second resistance component of target secondary battery 5 for monitoring may be calculated based on the impedance obtained, and the internal temperature of target secondary battery 5 for monitoring may be estimated based on the second resistance component value calculated and second relational expression E2.

As described above, the internal capacity of secondary battery 5 can be monitored based on reliable data, for instance, by estimating the internal temperature of secondary battery 5, based on the value of the second resistance component that varies with the battery state and second relational expression E2. Accordingly, reliability when monitoring the states of secondary batteries 5 can be enhanced.

### Embodiment 3

A battery monitoring device according to Embodiment 3 will be described.

### [Configuration of Battery Monitoring Device]

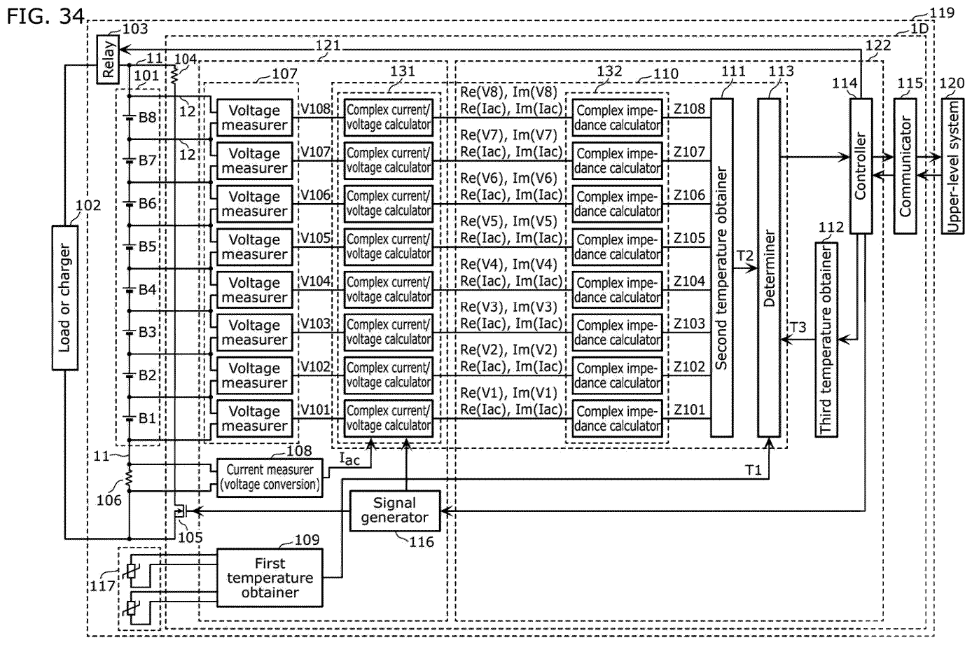

The configuration of the battery monitoring device according to Embodiment 3 will be described with reference to FIG. 34 to FIG. 47. In Embodiment 3, an example is described in which the state of a secondary battery is monitored and abnormalities of the secondary battery and the battery monitoring device are detected.

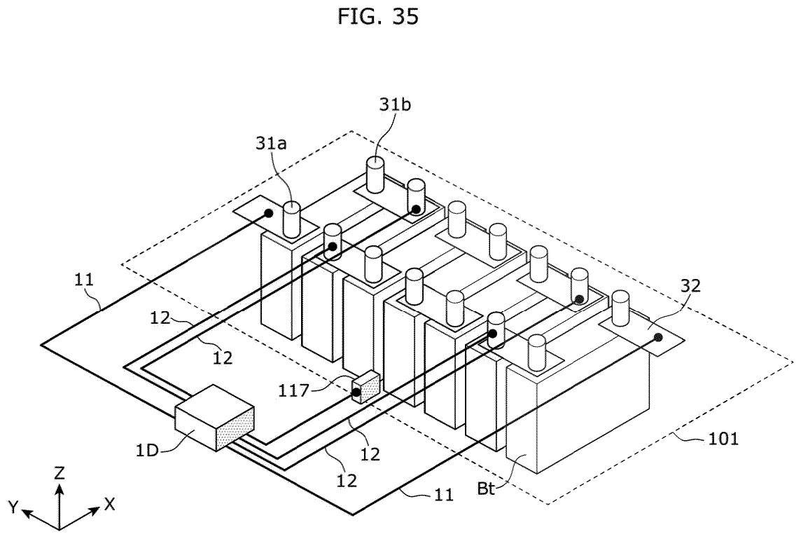

FIG. 34 is a schematic configuration diagram showing an example of battery monitoring device 1D according to Embodiment 3. FIG. 35 is a perspective view of battery monitoring device 1D according to Embodiment 3. Note that FIG. 34 also shows upper-level system 120, load 102, and relay 103 in addition to battery monitoring device 1D. FIG. 35 also shows battery pack 101, thermistor 117, current-application lines 11, and voltage-detection lines 12, for instance, in addition to battery monitoring device 1D.

As shown in FIG. 34 and FIG. 35, battery monitoring device 1D is connected to battery pack 101 in which secondary batteries B1 to B8 (hereinafter referred to as secondary batteries Bt) are combined and connected. Secondary batteries Bt are, for example, lithium-ion batteries, but are not limited thereto and may be other batteries such as nickel-hydrogen batteries.

Battery pack 101 functions as a power source for upper-level system 120 and load 102 (or a charger), and supplies power to upper-level system 120 and load 102 (or the charger).

Relay 103 that switches the connection between battery pack 101 and load 102 on and off is provided between battery pack 101 and load 102 (for example, a motor, an inverter, or an accelerator). In a vehicle, applications operate according to the on/off of connection between battery pack 101 and load 102 by relay 103. Note that when secondary batteries Bt are energy storage batteries, load 102 may be a charger.

Battery pack 101 and battery monitoring device 1D are connected by current-application lines 11 and voltage-detection lines 12. Current-application lines 11 are wires for applying an AC current to battery pack 101, and are, for example, conductors. Voltage-detection lines 12 are wires for detecting the voltages of secondary batteries Bt and are, for example, conductors. As shown in FIG. 35, voltage-detection lines 12 are connected to positive-electrode battery terminals 31a and negative-electrode battery terminals 31b of secondary batteries Bt. In the example shown in FIG. 35, sixteen voltage-detection lines 12 are provided for eight batteries.

Battery monitoring device 1D measures the complex impedances (for example, the individual internal AC impedances) of secondary batteries Bt, based on the AC current flowing through battery pack 101 and the AC voltages applied to secondary batteries Bt included in battery pack 101. For example, battery monitoring device 1D uses electrochemical impedance spectroscopy (EIS) to measure complex impedance characteristics of secondary batteries Bt and monitors the states of secondary batteries Bt in real time.

As shown in FIG. 34, battery monitoring device 1D includes measurer 121, arithmetic processor 110, controller 114, and communicator 115.

Note that battery monitoring unit 122 includes a part of arithmetic processor 110, controller 114, and third temperature obtainer 112. Battery monitoring system 119 includes reference resistor 106, thermistor 117 for measuring the external temperatures of secondary batteries Bt, load resistor 104, and switching element 105. Load resistor 104 and battery pack 101 are connected via current-application lines 11.

Measurer 121 shown in FIG. 34 includes voltage measurer 107 that measures voltages of battery pack 101, complex current/voltage calculator 131 that calculates complex currents and voltages, current measurer 108 that measures currents, first temperature obtainer 109 that obtains first temperature T1 which is the external temperature, and signal generator 116.

First temperature obtainer 109 obtains first temperature T1, which is the external temperature (or the surface temperature) of battery pack 101. First temperature obtainer 109 obtains first temperature T1, based on a signal output from thermistor 117 provided on the surface of battery pack 101, for example. Thermistor 117 is, for example, disposed on a side portion of battery pack 101. Note that thermistor 117 may be disposed at a terminal portion of battery pack 101 or on one of bus bars 32 (refer to FIG. 35) that connect the secondary batteries in series or parallel, for instance. Stated differently, thermistors 117 may be provided at multiple locations of battery pack 101. Thermistor 117 may be a temperature sensor for which another element such as a thermocouple is used.

Voltage measurer 107 is connected to secondary batteries Bt via voltage-detection lines 12 and measures the voltages of secondary batteries Bt. Voltage measurer 107 may measure the voltages of all of secondary batteries Bt included in battery pack 101. Note that voltage measurer 107 may measure the voltages of one or more (for example, at least two) of secondary batteries Bt included in battery pack 101. In other words, battery pack 101 may include one or more secondary batteries Bt whose voltages are not measured by voltage measurer 107.

Voltage measurer 107 measures the voltages of secondary batteries Bt included in battery pack 101 at the measurement timing set by arithmetic processor 110 so that the voltages are measured at the same timing.

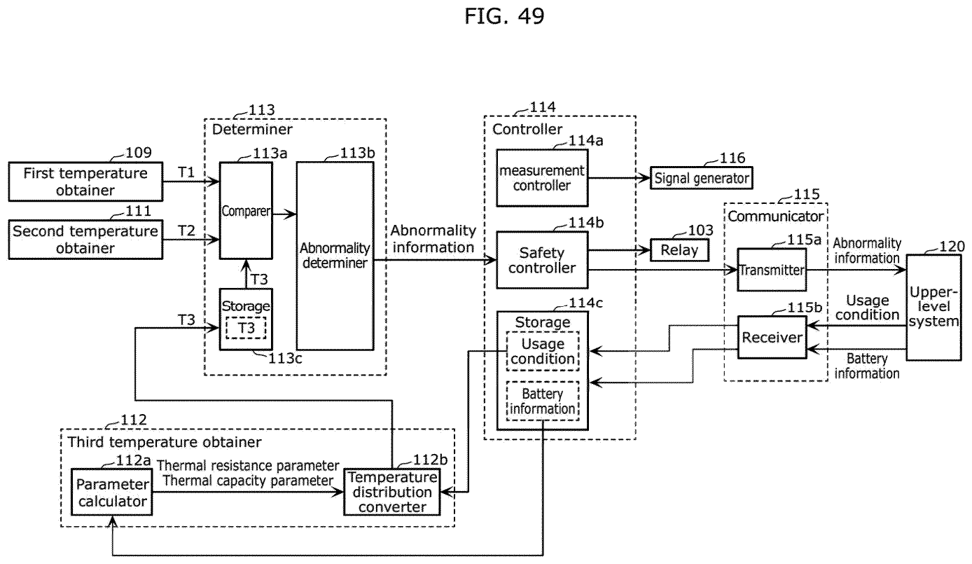

Load resistor 104 and switching element 105 are electrical elements for measuring the internal AC impedance of battery pack 101. For example, measurement controller 114a (refer to FIG. 49) of arithmetic processor 110 can turn on/off switching element 105 at specific frequencies, by controlling signal generator 116 that sweeps an AC signal. Accordingly, AC currents at specific frequencies are output from battery pack 101.

Voltage measurer 107 measures voltages across the terminals of secondary batteries Bt. Complex current/voltage calculator 131 calculates complex currents and voltages, based on measured voltages V101 to V108 obtained by voltage measurer 107. Real-axis voltage Re(V), imaginary-axis voltage Im(V), real-axis current Re(Iac), and imaginary-axis current Im(Iac) obtained by complex current/voltage calculator 131 are output to complex impedance calculator 132 of arithmetic processor 110.

As shown in FIG. 34, arithmetic processor 110 includes complex impedance calculator 132, second temperature obtainer 111, third temperature obtainer 112, and determiner 113.

Complex impedance calculator 132 calculates complex impedances Z101 to Z108, based on real-axis voltage Re(V), imaginary-axis voltage Im(V), real-axis current Re(Iac), and imaginary-axis current Im(Iac) output from complex current/voltage calculator 131. Complex impedances Z101 to Z108 obtained by complex impedance calculator 132 are output to second temperature obtainer 111.

Second temperature obtainer 111 obtains second temperatures T2, which are the internal temperatures of secondary batteries Bt, based on complex impedances Z101 to Z108 of secondary batteries Bt. Second temperature obtainer 111 obtains second temperatures T2 according to a temperature conversion table stored in a storage (not shown). The temperature conversion table is, for example, represented by a relational expression when the horizontal axis indicates the temperature and the vertical axis indicates the impedance value. This relational expression follows the Arrhenius law, exhibiting a tendency that the impedance value decreases as the temperature increases. Note that second temperature obtainer 111 may estimate the internal temperatures of secondary batteries Bt by the method shown in Embodiment 2.

Third temperature obtainer 112 obtains third temperature T3 including temperature distribution information of battery pack 101. The temperature distribution information includes information on arrangement and temperatures of secondary batteries Bt.

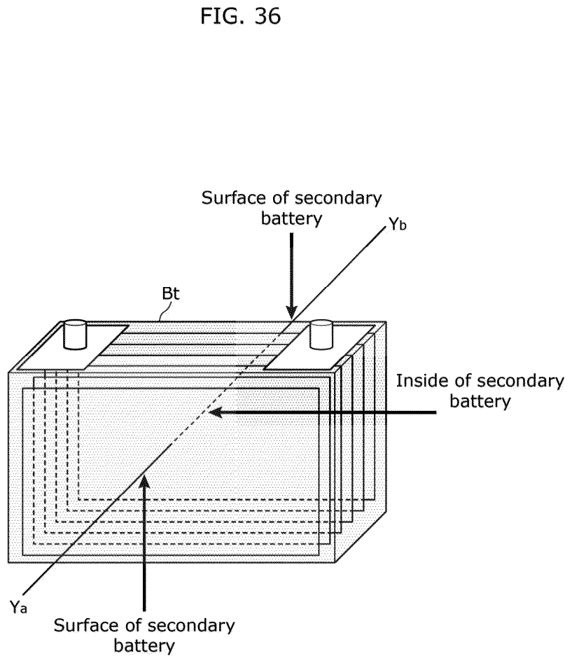

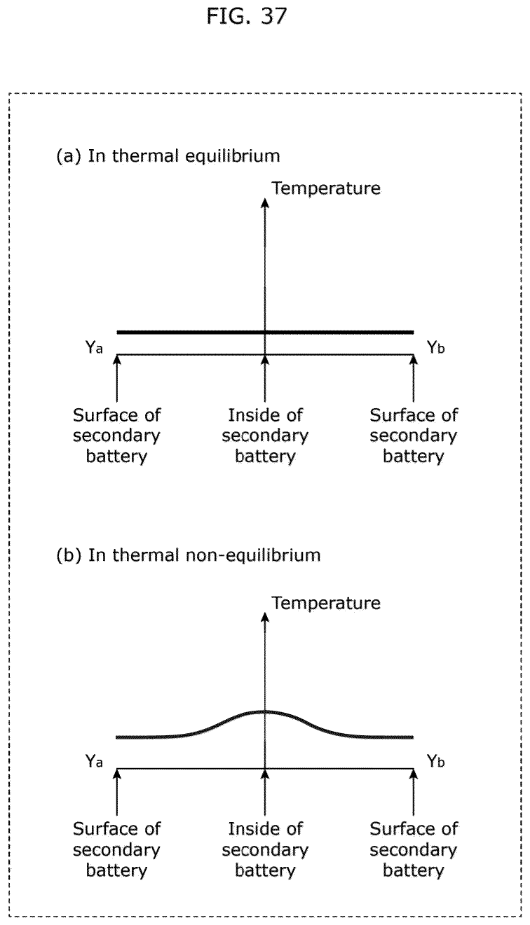

FIG. 36 shows the appearance of secondary battery Bt. FIG. 37 shows temperature distributions of secondary battery Bt.

FIG. 37 shows the temperature distribution of secondary battery Bt along line Ya-Yb in FIG. 36. In FIG. 37, (a) shows the temperature distribution of secondary battery Bt in thermal equilibrium, and (b) shows the temperature distribution of secondary battery Bt in thermal non-equilibrium. Note that the term thermal equilibrium refers to a state in which secondary battery Bt is inactive and not being charged or discharged. The term thermal non-equilibrium refers to a state in which secondary battery Bt is active and being charged or discharged.

As shown in (a) of FIG. 37, the external temperature and the internal temperature of secondary battery Bt in thermal equilibrium are the same. On the other hand, as shown in (b) of FIG. 37, the external temperature and the internal temperature of secondary battery Bt in thermal non-equilibrium are different. In this example, the internal temperature during thermal non-equilibrium is higher than the external temperature. Note that the external temperature of secondary battery Bt refers to the temperature in an outer portion of secondary battery Bt, including the surface temperature of secondary battery Bt.

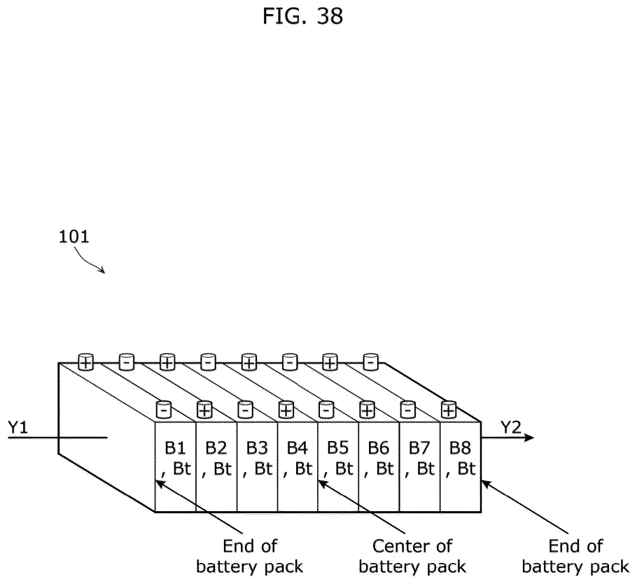

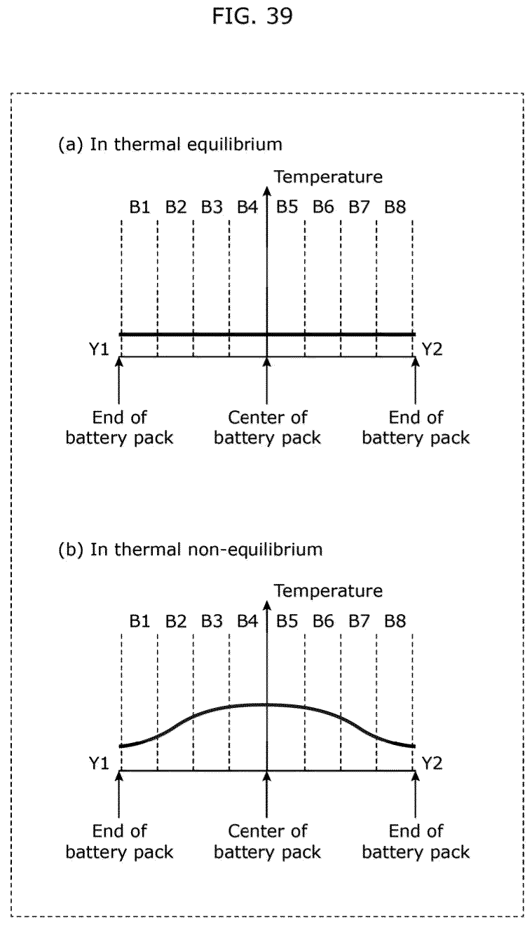

FIG. 38 shows the appearance of battery pack 101. FIG. 39 shows temperature distributions of battery pack 101.

FIG. 39 shows temperature distributions of battery pack 101 along line Y1-Y2 in FIG. 38. Note that FIG. 39 includes diagrams showing plotted average values of the temperatures of secondary batteries B1 to B8 with curve fitting. In FIG. 39, (a) shows the temperature distribution of battery pack 101 in thermal equilibrium, and (b) shows the temperature distribution of battery pack 101 in thermal non-equilibrium. In this example, the temperatures of secondary batteries B4 and B5 disposed near the center of battery pack 101 are higher than the temperatures of secondary batteries B1 and B8 disposed at the ends of battery pack 101.

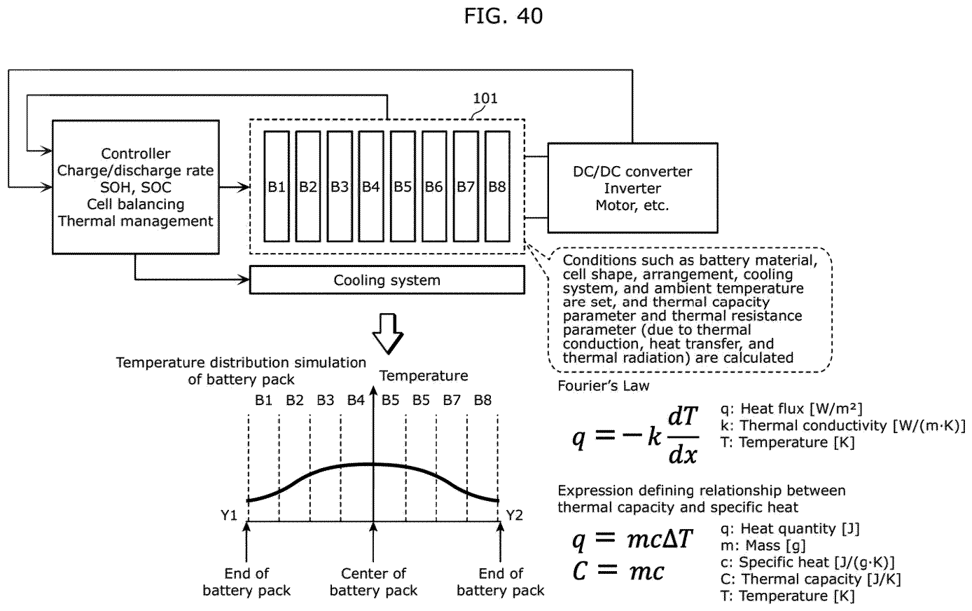

FIG. 40 shows an example of deriving a temperature distribution of battery pack 101.

FIG. 40 shows an example of deriving a temperature distribution of battery pack 101 using simulation software such as a pseudo two-dimensional electrochemical model. First, in a computing device, a battery model is created by inputting information on secondary batteries Bt, and parameters of battery pack 101 are derived based on the battery model. Furthermore, parameters used in battery pack 101 and usage conditions are input to the battery model, and the temperature distribution of battery pack 101 is obtained.

Third temperature obtainer 112 obtains the temperature distribution of battery pack 101 using the above simulation software.

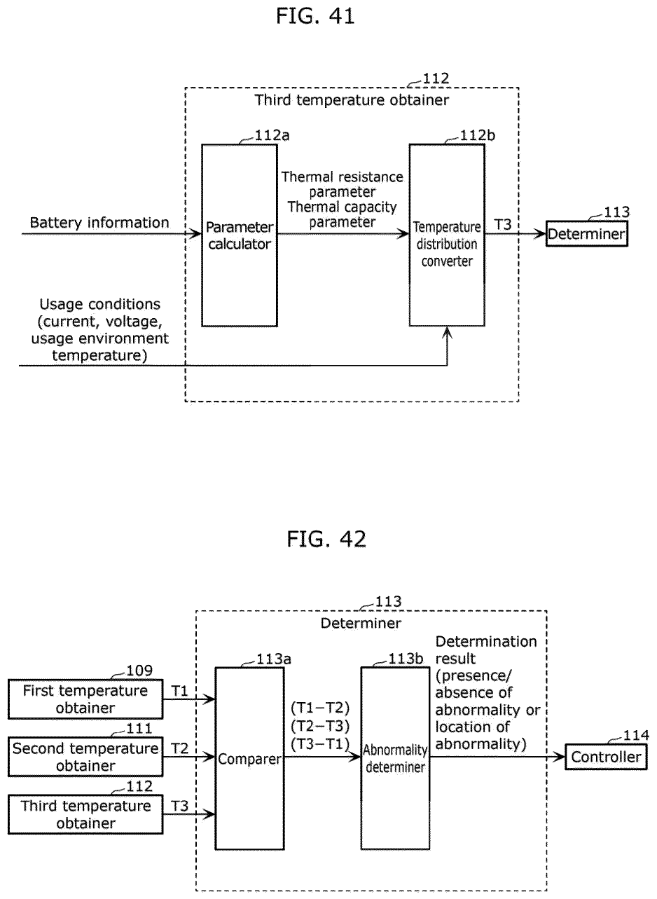

FIG. 41 shows third temperature obtainer 112 of battery monitoring device 1D.

As shown in FIG. 41, third temperature obtainer 112 includes parameter calculator 112a and temperature distribution converter 112b.

Parameter calculator 112a calculates parameters of battery pack 101 based on information on secondary batteries Bt. The information on secondary batteries Bt includes information on at least one of the material of each secondary battery Bt, a shape of each secondary battery Bt, an arrangement of secondary batteries Bt, or a cooling system of secondary batteries Bt. The information on secondary batteries Bt is input to parameter calculator 112a via upper-level system 120, communicator 115, and controller 114, for example.

Parameter calculator 112a outputs parameters of battery pack 101, based on information on secondary batteries Bt. The parameters of battery pack 101 include information on a thermal resistance parameter and a thermal capacity parameter of battery pack 101.

The thermal resistance parameter is represented by Expression 6 in the following, for example.

$$q = - k \cdot dT / dx \qquad ( Expression 6 )$$

$$q : heat flux [ W / {m}^{2} ]$$

$$k : thermal conductivity [ W / ( m \cdot K ) ]$$

$$T : temperature [ K ]$$

The thermal capacity parameter is represented by Expression 7 in the following, for example.

$$q = mc Δ T \qquad ( Expression 7 )$$

$$C = mc$$

$$q : heat quantity [ J ]$$

$$m : mass [ g ]$$

$$c : specific heat [ J / ( g \cdot K ) ]$$

$$C : thermal capacity [ J / K ]$$

$$T : temperature [ K ]$$

Temperature distribution converter 112b calculates temperature distribution information, based on the parameters of battery pack 101 output from parameter calculator 112a and the usage conditions of battery pack 101 separately output from controller 114. The parameters of battery pack 101 include information on at least one of the thermal resistance parameter or the thermal capacity parameter. The usage conditions of battery pack 101 include information on at least one of the current flowing through secondary batteries Bt, the voltages applied to secondary batteries Bt, or the usage environment temperature of battery pack 101. The usage conditions of battery pack 101 are input to temperature distribution converter 112b via upper-level system 120, communicator 115, and controller 114, for example. Temperature distribution converter 112b derives third temperature T3 including temperature distribution information, based on the parameters of battery pack 101 and the usage conditions of battery pack 101, and outputs third temperature T3 to determiner 113.

Determiner 113 determines whether an abnormality is present in first temperature T1, second temperature T2, or third temperature T3 by obtaining differences among first temperature T1, second temperature T2, and third temperature T3.

FIG. 42 shows determiner 113 of battery monitoring device 1D.

As shown in FIG. 42, determiner 113 includes comparer 113a and abnormality determiner 113b.

Comparer 113a compares first temperature T1 output from first temperature obtainer 109, second temperature T2 output from second temperature obtainer 111, and third temperature T3 output from third temperature obtainer 112 with one another. Specifically, comparer 113a compares first temperature T1 and second temperature T2 and calculates difference |T1−T2|, which is the difference between first temperature T1 and second temperature T2. Furthermore, comparer 113a compares second temperature T2 and third temperature T3 and calculates difference |T2−T3|, which is the difference between second temperature T2 and third temperature T3. Comparer 113a further compares third temperature T3 and first temperature T1 and calculates difference |T3−T1|, which is the difference between third temperature T3 and first temperature T1. Each of differences |T1−T2|, |T2−T3|, and |T3−T1| may be a specific value or may be curve data with the coordinates of secondary batteries Bt on the horizontal axis and the temperature thereof on the vertical axis. Comparer 113a outputs the differences obtained by the comparisons to abnormality determiner 113b.

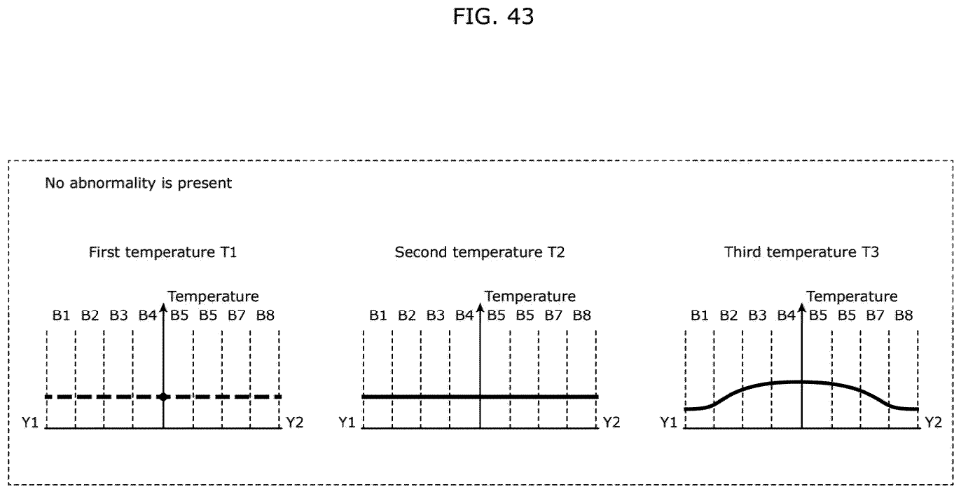

FIG. 43 is a diagram showing an example when no abnormality is present in first temperature T1, second temperature T2, and third temperature T3.

FIG. 43 shows an example in which the differences among first temperature T1, second temperature T2, and third temperature T3 are substantially the same. Abnormality determiner 113b determines that no abnormality is present in first temperature T1, second temperature T2, and third temperature T3 when the differences among first temperature T1, second temperature T2, and third temperature T3 are below a predetermined threshold.

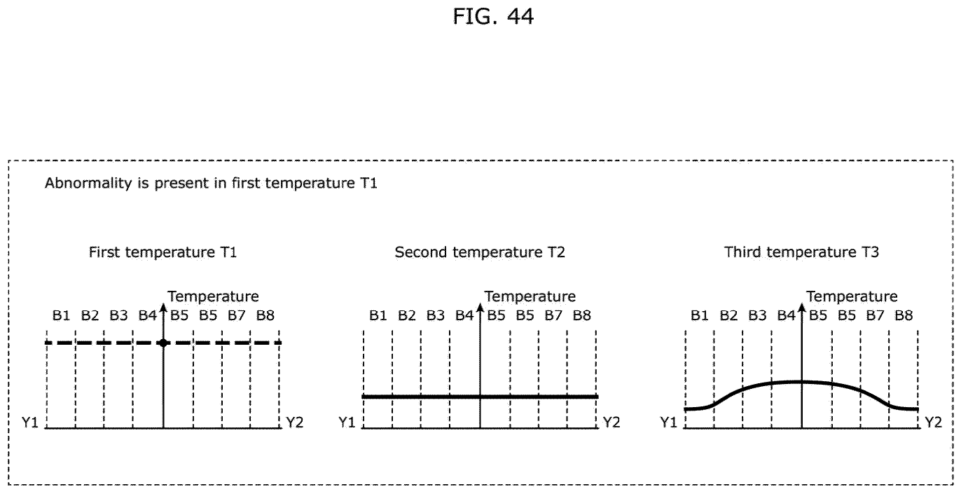

FIG. 44 shows an example in which an abnormality is present in first temperature T1.

FIG. 44 shows an example in which first temperature T1 differs significantly from second temperature T2 and third temperature T3. Abnormality determiner 113b determines that an abnormality is present in the measurement of first temperature T1 when each of differences |T1−T2| and |T3−T1| is greater than or equal to a first threshold. The first threshold may be a variable value such as difference |T2−T3| or may be a predetermined fixed value. The first threshold may be a value obtained by multiplying difference |T2−T3| by a coefficient. For example, abnormality determiner 113b determines that an abnormality has occurred in thermistor 117, when the differences are each greater than or equal to the first threshold.

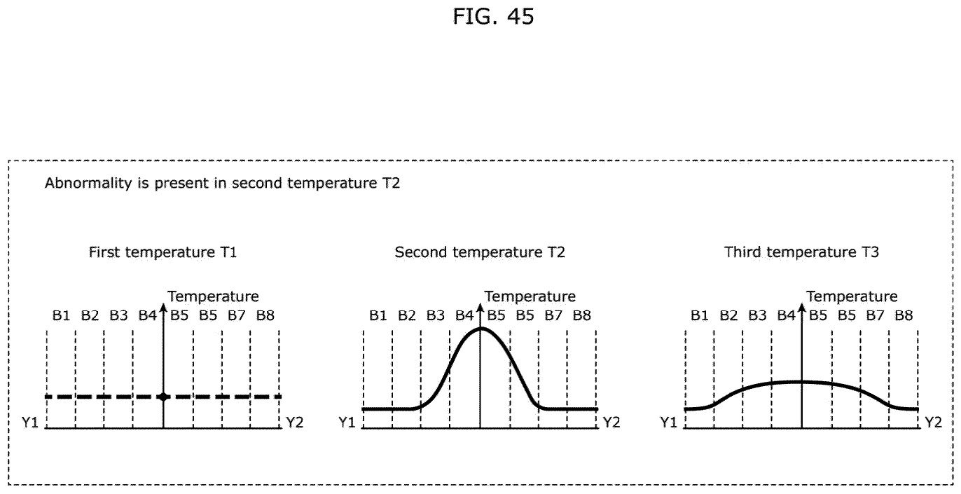

FIG. 45 shows an example in which an abnormality is present in second temperature T2.

FIG. 45 shows an example in which second temperature T2 differs significantly from first temperature T1 and third temperature T3. Abnormality determiner 113b determines that an abnormality is present in the measurement of second temperature T2 when differences |T1−T2| and |T2−T3| are each greater than or equal to a second threshold. The second threshold may be a variable value such as difference |T3−T1| or may be a predetermined fixed value. The second threshold may be a value obtained by multiplying difference |T3−T1| by a coefficient. For example, abnormality determiner 113b determines that an abnormality has occurred in the measurement of the complex impedance, when the differences are each greater than or equal to the second threshold.

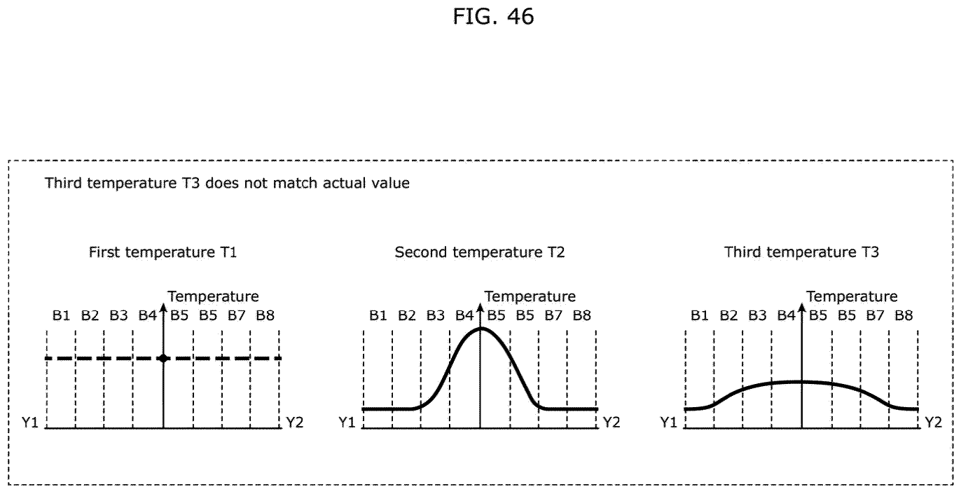

FIG. 46 shows an example in which an abnormality is present in third temperature T3.

FIG. 46 shows an example in which third temperature T3 differs significantly from first temperature T1 and second temperature T2. Abnormality determiner 113b determines that third temperature T3 does not match the actual temperature distribution when differences |T2−T3| and |T3−T1| are each greater than or equal to a third threshold. The third threshold may be a variable value such as difference |T1−T2| or may be a predetermined fixed value. The third threshold may be a value obtained by multiplying difference |T1−T2| by a coefficient. For example, abnormality determiner 113b determines that abnormal heating is occurring in secondary battery Bt (for example, heating of secondary battery Bt itself or failure of the cooling system), when the differences are each greater than or equal to the third threshold.

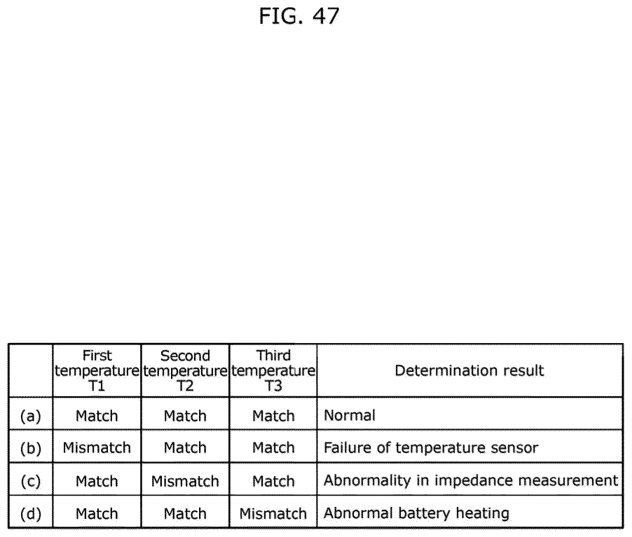

FIG. 47 shows a list of determination results of determiner 113.

In FIG. 47, (a) shows the case where no abnormality is present in first temperature T1, second temperature T2, and third temperature T3. In FIG. 47, (b) shows the case where an abnormality are present in first temperature T1, (c) shows the case where an abnormality is present in second temperature T2, and (d) shows the case where an abnormality is present in third temperature T3. Battery monitoring device 1D determines whether operation of battery monitoring device 1D is to be continued or stopped, based on the determination results shown in FIG. 47.

Battery monitoring device 1D according to the present embodiment includes: first temperature obtainer 109 that obtains first temperature T1 that is an external temperature of battery pack 101 that includes plural secondary batteries Bt; second temperature obtainer 111 that obtains second temperature T2 that is an internal temperature of each of plural secondary batteries Bt; third temperature obtainer 112 that obtains third temperature T3 that includes temperature distribution information of battery pack 101; and determiner 113 that compares first temperature T1, second temperature T2, and third temperature T3 and determines, for each of first temperature T1, second temperature T2, and third temperature T3, whether an abnormality is present. According to this configuration, the temperature states of secondary batteries Bt can be monitored and temperature abnormalities of secondary batteries Bt can be detected. Accordingly, reliability when monitoring the states of secondary batteries Bt can be enhanced.

### [Operation of Battery Monitoring Device]

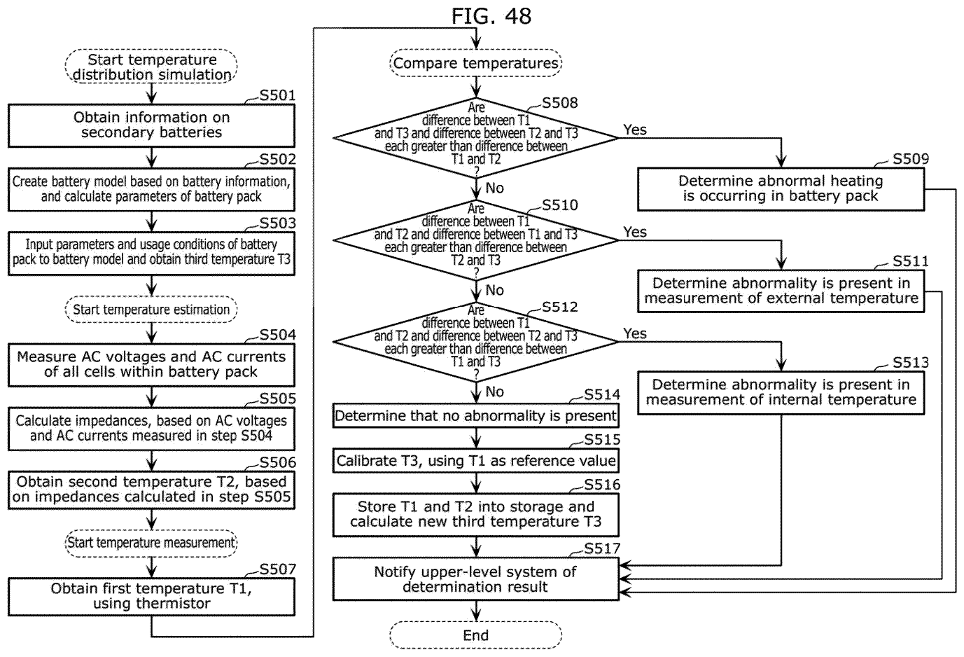

The operation of battery monitoring device 1D according to Embodiment 3 will be described with reference to FIG. 48.

FIG. 48 shows an operation flow of battery monitoring device 1D according to Embodiment 3.

First, battery monitoring device 1D starts simulation of the temperature distribution of battery pack 101.

Battery monitoring device 1D obtains information on secondary batteries Bt (step S501). The information on secondary batteries Bt is, for example, information on the material of each secondary battery Bt, the shape of each secondary battery Bt, the arrangement of secondary batteries Bt, and the cooling system of secondary batteries Bt.

Next, battery monitoring device 1D creates a battery model of secondary batteries Bt, based on the battery information obtained in step S501 and calculates parameters of battery pack 101 (step S502). The parameters of battery pack 101 are, for example, a thermal resistance parameter and a thermal capacity parameter of battery pack 101.

Next, battery monitoring device 1D inputs the parameters and the usage conditions of battery pack 101 into the battery model and obtains third temperature T3, which is the temperature distribution of battery pack 101 (step S503). The usage conditions of battery pack 101 are, for example, currents flowing through secondary batteries Bt, voltages applied to secondary batteries Bt, and the usage environment temperature of battery pack 101.

Furthermore, battery monitoring device 1D starts estimation of the internal temperature of battery pack 101.

Battery monitoring device 1D measures AC voltages and AC currents of all the cells within battery pack 101 (step S504).

Next, battery monitoring device 1D calculates impedances, based on the AC voltages and the AC currents measured in step S504 (step S505).

Next, battery monitoring device 1D obtains second temperature T2, which is the internal temperature of battery pack 101, based on the impedances calculated in step S505 (step S506).

Furthermore, battery monitoring device 1D starts measurement of the external temperature of battery pack 101.

Battery monitoring device 1D obtains first temperature T1, which is the external temperature of battery pack 101, using thermistor 117 provided on the surface of battery pack 101 (step S507).

Then, battery monitoring device 1D compares the temperatures obtained in steps S501 to S507.

Battery monitoring device 1D determines whether each of difference |T3−T1| between first temperature T1 and third temperature T3 and difference |T2−T3| between second temperature T2 and third temperature T3 is greater than difference |T1−T2| between first temperature T1 and second temperature T2 (step S508).

When each of the differences is greater (Yes in S508), battery monitoring device 1D determines that abnormal heating (for example, heating of secondary battery Bt itself or failure of the cooling system) is occurring in battery pack 101 (step S509). When the differences are not greater (No in S508), battery monitoring device 1D performs the following determination.

Battery monitoring device 1D determines whether each of difference |T1−T2| between first temperature T1 and second temperature T2 and difference |T3−T1| between first temperature T1 and third temperature T3 is greater than difference |T2−T3| between second temperature T2 and third temperature T3 (step S510).

When the differences are greater (Yes in S510), battery monitoring device 1D determines that an abnormality is present in the measurement of the external temperature (step S511). When the differences are not greater (No in S510), battery monitoring device 1D performs the following determination.

Battery monitoring device 1D determines whether each of difference |T1−T2| between first temperature T1 and second temperature T2 and difference |T2−T3| between second temperature T2 and third temperature T3 is greater than difference |T3−T1| between first temperature T1 and third temperature T3 (step S512).

When the differences are greater (Yes in S512), battery monitoring device 1D determines that an abnormality exists in the measurement of the internal temperature (step S513). When the differences are not greater (No in S512), battery monitoring device 1D determines that no abnormality is present in first temperature T1, second temperature T2, and third temperature T3 (step S514).

Then, battery monitoring device 1D calibrates third temperature T3, as necessary, using first temperature T1 as a reference value (step S515).

Furthermore, battery monitoring device 1D stores first temperature T1 and second temperature T2 into storage 113c and derives new third temperature T3, as necessary (step S516). Battery monitoring device 1D then notifies upper-level system 120 of the determination results obtained in steps S509, S511, S513, and S514 (step S517).

By executing these steps, battery monitoring device 1D can monitor the temperature states of secondary batteries Bt and detect temperature abnormalities of secondary batteries Bt. Accordingly, reliability when monitoring the states of secondary batteries Bt can be enhanced.

In the above, an example is shown in which step S507 is executed after steps S504 to S506, but step S507 may be executed simultaneously with steps S504 to S506. Furthermore, an example is shown in which steps S504 to S507 are executed after steps S501 to S503, but steps S504 to S507 may be executed simultaneously with steps S501 to S503 or may be executed before steps S501 to S503.

### [Variation of Embodiment 3]

Battery monitoring device 1D according to a variation of Embodiment 3 will be described with reference to FIG. 49. In this variation, an example is described in which accidents due to temperature abnormalities are prevented in advance and a user is notified when an abnormal state occurs.

FIG. 49 is a block diagram showing part of battery monitoring device 1D according to the variation of Embodiment 3. The figure also shows measurement controller 114a and signal generator 116.

In battery monitoring device 1D according to the variation, third temperature obtainer 112 is included in battery monitoring device 1D, a battery model is created in battery monitoring device 1D, and third temperature T3 is calculated. The inclusion of third temperature obtainer 112 in battery monitoring device 1D allows real-time monitoring.

First, information on secondary batteries Bt and usage conditions of battery pack 101 is obtained from upper-level system 120 via communicator 115 that includes transmitter 115a and receiver 115b, and the obtained information is stored into storage 114c.

Next, the battery information stored in storage 114c is input to parameter calculator 112a, and a thermal resistance parameter and a thermal capacity parameter are calculated. The thermal resistance parameter and the thermal capacity parameter are input to temperature distribution converter 112b, and by further inputting the usage conditions of battery pack 101, third temperature T3 including temperature distribution information of battery pack 101 is calculated.

Next, calculated third temperature T3 is input to determiner 113, and the presence or absence of abnormalities in battery pack 101 and the location where any abnormality has occurred are determined based on the magnitude relation of first temperature T1, second temperature T2, and third temperature T3.

Determiner 113 outputs the determination result to safety controller 114b. Safety controller 114b controls the operation of relay 103 connected in series to battery pack 101, based on this determination result. For example, safety controller 114b causes relay 103 connected to battery pack 101 to be non-conductive when the determination result indicates an abnormality. Accordingly, accidents due to temperature abnormalities of battery pack 101 can be prevented in advance.

Safety controller 114b transmits the determination result indicating an abnormality to upper-level system 120 via communicator 115. For example, upper-level system 120 is a terminal device such as a smartphone. The communication method via communicator 115 is wireless communication such as Wi-Fi (registered trademark), Bluetooth (registered trademark), or NFC (registered trademark), for example. Note that the communication method is not limited to wireless communication, and may be wired communication such as USB (registered trademark), CAN (registered trademark), or UART (registered trademark) communication. By transmitting abnormality information to upper-level system 120, it is possible to notify the user that secondary battery Bt or battery monitoring device 1D is in an abnormal state.

### (Summary of Embodiment 3)

Aspects of battery monitoring device 1D according to Embodiment 3 will be described.

Battery monitoring device 1D according to Aspect 1 includes: first temperature obtainer 109 that obtains first temperature T1 that is an external temperature of battery pack 101 that includes plural secondary batteries Bt; second temperature obtainer 111 that obtains second temperature T2 that is an internal temperature of each of plural secondary batteries Bt; third temperature obtainer 112 that obtains third temperature T3 that includes temperature distribution information of battery pack 101; and determiner 113 that compares first temperature T1, second temperature T2, and third temperature T3 and determines, for each of first temperature T1, second temperature T2, and third temperature T3, whether an abnormality is present.

As described above, the temperature state of secondary batteries Bt can be monitored and temperature abnormalities of secondary batteries Bt can be detected by comparing first temperature T1, which is the external temperature of battery pack 101, second temperature T2, which is the internal temperature of secondary battery Bt, and third temperature T3, which includes temperature distribution information of battery pack 101. Accordingly, reliability when monitoring the states of secondary batteries Bt can be enhanced.

Battery monitoring device 1D according to Aspect 2 is the battery monitoring device according to Aspect 1 in which first temperature obtainer 109 may obtain first temperature T1, based on an output signal from thermistor 117 provided on a surface of battery pack 101.

According to this, first temperature T1 can be appropriately obtained. Accordingly, the temperature states of secondary batteries Bt can be monitored and temperature abnormalities of secondary batteries Bt can be detected. Accordingly, reliability when monitoring the states of secondary batteries Bt can be enhanced.

Battery monitoring device 1D according to Aspect 3 is the battery monitoring device according to Aspect 1 or 2 in which second temperature obtainer 111 may obtain second temperature T2, based on an impedance of each of plural secondary batteries Bt.

According to this, second temperature T2 can be appropriately obtained. Accordingly, the temperature states of secondary batteries Bt can be monitored, and temperature abnormalities of secondary batteries Bt can be detected. Accordingly, reliability when monitoring the states of secondary batteries Bt can be enhanced.

Battery monitoring device 1D according to Aspect 4 is the battery monitoring device according to any one of Aspects 1 to 3 in which the temperature distribution information may include information on an arrangement and temperatures of plural secondary batteries Bt.

According to this, third temperature T3, which includes information on the arrangement and temperatures of secondary batteries Bt, can be appropriately obtained. Accordingly, the temperature states of secondary batteries Bt can be monitored, and temperature abnormalities of secondary batteries Bt can be detected. Accordingly, reliability when monitoring the states of secondary batteries Bt can be enhanced.

Battery monitoring device 1D according to Aspect 5 is the battery monitoring device according to any one of Aspects 1 to 4 in which third temperature obtainer 112 may obtain the temperature distribution information by inputting a parameter of battery pack 101 and a usage condition of battery pack 101 into a battery model created based on information on plural secondary batteries Bt.

According to this, third temperature T3 including temperature distribution information can be appropriately obtained based on the battery model. Accordingly, the temperature states of secondary batteries Bt can be monitored, and temperature abnormalities of secondary batteries Bt can be detected. Accordingly, reliability when monitoring the states of secondary batteries Bt can be enhanced.

Battery monitoring device 1D according to Aspect 6 is the battery monitoring device according to Aspect 5 in which the information on plural secondary batteries Bt may include information on at least one of a material of each of plural secondary batteries Bt, a shape of each of plural secondary batteries Bt, an arrangement of plural secondary batteries Bt, or a cooling system of plural secondary batteries Bt.

According to this, the battery model of battery pack 101 can be appropriately created, and third temperature T3 including temperature distribution information can be appropriately obtained. Accordingly, the temperature states of secondary batteries Bt can be monitored, and temperature abnormalities of secondary batteries Bt can be detected. Accordingly, reliability when monitoring the states of secondary batteries Bt can be enhanced.

Battery monitoring device 1D according to Aspect 7 is the battery monitoring device according to Aspect 5 in which the parameter of battery pack 101 may include information on at least one of a thermal resistance parameter or a thermal capacity parameter of battery pack 101.

According to this, third temperature T3 including temperature distribution information can be appropriately obtained using the battery model of battery pack 101. Accordingly, the temperature states of secondary batteries Bt can be monitored, and temperature abnormalities of secondary batteries Bt can be detected. Accordingly, reliability when monitoring the states of secondary batteries Bt can be enhanced.

Battery monitoring device 1D according to Aspect 8 is the battery monitoring device according to Aspect 5 in which the usage condition of battery pack 101 may include at least one of a current flowing through each of plural secondary batteries Bt, a voltage applied to each of plural secondary batteries Bt, or a usage environment temperature of battery pack 101.

According to this, third temperature T3 including temperature distribution information can be appropriately obtained using the battery model of battery pack 101. Accordingly, the temperature states of secondary batteries Bt can be monitored, and temperature abnormalities of secondary batteries Bt can be detected. Accordingly, reliability when monitoring the states of secondary batteries Bt can be enhanced.

Battery monitoring device 1D according to Aspect 9 is the battery monitoring device according to any one of Aspects 1 to 8 in which determiner 113 may determine, for each of first temperature T1, second temperature T2, and third temperature T3, whether an abnormality is present by obtaining differences among first temperature T1, second temperature T2, and third temperature T3.

By obtaining the differences among first temperature T1, second temperature T2, and third temperature T3 in this manner, the temperature states of secondary batteries Bt can be monitored and temperature abnormalities of secondary batteries Bt can be detected. Accordingly, reliability when monitoring the states of secondary batteries Bt can be enhanced.

Battery monitoring device 1D according to Aspect 10 is the battery monitoring device according to any one of Aspects 1 to 9 in which determiner 113 may determine that no abnormality is present in first temperature T1, second temperature T2, and third temperature T3 when differences among first temperature T1, second temperature T2, and third temperature T3 are each below a predetermined threshold.

According to this, it is possible to accurately determine that no abnormality is present in first temperature T1, second temperature T2, and third temperature T3. Accordingly, reliability when monitoring the states of secondary batteries Bt can be enhanced.

Battery monitoring device 1D according to Aspect 11 is the battery monitoring device according to any one of Aspects 1 to 9 in which determiner 113 may determine that an abnormality is present in measurement of first temperature T1 when a difference between second temperature T2 and first temperature T1 and a difference between third temperature T3 and first temperature T1 are each greater than or equal to a first threshold.

According to this, it is possible to accurately determine that an abnormality is present in first temperature T1. Accordingly, reliability when monitoring the states of secondary batteries Bt can be enhanced.

Battery monitoring device 1D according to Aspect 12 is the battery monitoring device according to any one of Aspects 1 to 9 in which determiner 113 may determine that an abnormality is present in measurement of second temperature T2 when a difference between first temperature T1 and second temperature T2 and a difference between third temperature T3 and second temperature T2 are each greater than or equal to a second threshold.

According to this, it is possible to accurately determine that an abnormality is present in second temperature T2. Accordingly, reliability when monitoring the states of secondary batteries Bt can be enhanced.

Battery monitoring device 1D according to Aspect 13 is the battery monitoring device according to any one of Aspects 1 to 9 in which determiner 113 may determine that third temperature T3 does not match an actual temperature distribution when a difference between first temperature T1 and third temperature T3 and a difference between second temperature T2 and third temperature T3 are each greater than or equal to a third threshold.

According to this, it is possible to accurately determine that third temperature T3 does not match the actual temperature distribution. Accordingly, reliability when monitoring the states of secondary batteries Bt can be enhanced.

Battery monitoring device 1D according to Aspect 14 is the battery monitoring device according to any one of Aspects 1 to 13, which may further include: safety controller 114b that controls operation of relay 103 connected in series to battery pack 101, based on a determination result of determiner 113.

Accordingly, accidents due to temperature abnormalities of battery pack 101 can be prevented in advance, and a user can be notified that an abnormal state has occurred.

Battery monitoring device 1D according to Aspect 15 is the battery monitoring device according to any one of Aspects 1 to 13, which may further include: storage 24 that stores relational data indicating, for each of the plurality of secondary batteries, a relationship between a state of the secondary battery and a resistance component that varies with the state of the secondary battery, among a plurality of resistance components included in an impedance of the secondary battery; impedance obtainer 23a that obtains an impedance of a target secondary battery for monitoring, among the plurality of secondary batteries; and arithmetic processer 23 that calculates, based on the impedance obtained by impedance obtainer 23a, a value of a resistance component that varies with a state of the target secondary battery for monitoring, and estimates the state of the target secondary battery for monitoring, based on the value of the resistance component calculated and the relational data.

As described above, the state of a secondary battery can be monitored based on reliable data, for instance, by estimating the state of the secondary battery based on the value of the resistance component that varies with the battery state and the relational data described above. Accordingly, reliability when monitoring the states of the secondary batteries can be enhanced.

Battery monitoring device 1D according to Aspect 16 is the battery monitoring device according to Aspect 15 in which storage 24 may store, as the relational data, a first relational expression indicating, for each of the plurality of secondary batteries, a relationship between an amount of capacity loss of the secondary battery and a first resistance component that varies with the amount of capacity loss of the secondary battery, and arithmetic processer 23 may calculate a value of the first resistance component of the target secondary battery for monitoring, based on the impedance obtained by impedance obtainer 23a, and estimate an amount of capacity loss of the target secondary battery for monitoring, based on the value of the first resistance component calculated and first relational expression E1.

As described above, the amount of capacity loss of a secondary battery can be monitored based on reliable data, for instance, by estimating the amount of capacity loss of the secondary battery, based on the value of the first resistance component that varies with the battery state and first relational expression E1. Accordingly, reliability when monitoring the states of the secondary batteries can be enhanced.

Battery monitoring device 1D according to Aspect 17 is the battery monitoring device according to Aspect 15 in which storage 24 may store, as the relational data, second relational expression E2 indicating, for each of the plurality of secondary batteries, a relationship between an internal temperature of the secondary battery and a second resistance component that varies with the internal temperature of the secondary battery, and arithmetic processer 23B may calculate a value of the second resistance component of the target secondary battery for monitoring, based on the impedance obtained by impedance obtainer 23a, and estimate an internal temperature of the target secondary battery for monitoring, based on the value of the second resistance component calculated and second relational expression E2.

As described above, the internal capacity of a secondary battery can be monitored based on reliable data, for instance, by estimating the internal temperature of the secondary battery, based on the value of the second resistance component that varies with the battery state and second relational expression E2. Accordingly, reliability when monitoring the states of the secondary batteries can be enhanced.

A battery monitoring method according to Aspect 18 includes: obtaining first temperature T1 that is an external temperature of battery pack 101 that includes plural secondary batteries Bt; obtaining second temperature T2 that is an internal temperature of each of plural secondary batteries Bt; obtaining third temperature T3 that includes temperature distribution information of battery pack 101; and comparing first temperature T1, second temperature T2, and third temperature T3 and determining, for each of first temperature T1, second temperature T2, and third temperature T3, whether an abnormality is present.

As described above, the temperature states of secondary batteries Bt can be monitored and temperature abnormalities of secondary batteries Bt can be detected, by comparing first temperature T1, which is the external temperature of battery pack 101, second temperature T2, which is the internal temperature of secondary battery Bt, and third temperature T3, which includes temperature distribution information of battery pack 101. Accordingly, reliability when monitoring the states of secondary batteries Bt can be enhanced.

### OTHER EMBODIMENTS

The foregoing has described Embodiments 1, 2 and 3, but nevertheless, the present disclosure is not limited to the above embodiments.

For example, in Embodiment 1, resistance component III due to deposits is considered to be the first resistance component, but the present disclosure is not limited thereto. For example, when resistance component II due to the electrolyte and resistance component III due to deposits are each considered to be the first resistance component, first relational expression E1 may be expressed by the horizontal axis and the left vertical axis in FIG. 11.

For example, in the equivalent circuit shown in FIG. 3, a constant phase element (CPE) is used to represent an electrical double-layer capacitance (capacitor) of the impedance values (R4C4) and (R5C5). The impedance of a CPE includes CPE constant T and a CPE exponent, and is used as a convenient parameter introduced for shape adjustment in curve fitting when the capacitive semicircle in a Nyquist plot based on actual measurement is not a perfect circle. However, the present disclosure is not limited to the above method, and the number of RC arc stages may be increased in order to give chemical meaning to the electrical double-layer capacitance (capacitor) of the impedance values (R4C4) and (R5C5).

Furthermore, in the above example, the impedance values (R4C4) and (R5C5) are calculated by curve fitting using the equivalent circuit model, but the overvoltage at the negative and positive electrodes may be calculated using the Butler-Volmer equation and the impedance may be obtained therefrom. Alternatively, the electrochemical behavior of a battery may be simulated using simulation software (a pseudo-two-dimensional (P2D) electrochemical model) to obtain the impedance.

The circuit configuration described in the above embodiments is an example, and the present disclosure is not limited to the above circuit configuration. Thus, circuits that can implement distinctive functions of the present disclosure similarly to the above circuit configuration are also encompassed in the present disclosure. For example, within the scope that can implement functions similar to those of the above circuit configuration, a configuration in which an element such as a switching element (transistor), a resistive element, or a capacitive element is connected in series or in parallel to a given element is also encompassed in the present disclosure.

Furthermore, in the above embodiments, the elements included in an integrated circuit are realized by hardware. However, some of the elements included in the integrated circuit may be realized by executing software programs appropriate for those elements. Some of the elements included in the integrated circuit may be realized by a program executor such as a central processing unit (CPU) or a processor reading and executing software programs recorded on a recording medium such as a hard disk or semiconductor memory.

In the above embodiments, processing executed by a particular processing unit may be executed by another processing unit. Furthermore, in the operations described in the above embodiments, the order of plural processes may be changed, or plural processes may be performed in parallel.

The present disclosure also encompasses embodiments as a result of applying, to the embodiments, various modifications that may be conceived by those skilled in the art, and embodiments obtained by combining elements and functions in the embodiments in any manner as long as the combination does not depart from the scope of the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is useful as a battery monitoring device that monitors the states of secondary batteries.

1. A battery monitoring device comprising:
a first temperature obtainer that obtains a first temperature that is an external temperature of a battery pack that includes a plurality of secondary batteries;
a second temperature obtainer that obtains a second temperature that is an internal temperature of each of the plurality of secondary batteries;
a third temperature obtainer that obtains a third temperature that includes temperature distribution information of the battery pack; and
a determiner that compares the first temperature, the second temperature, and the third temperature and determines, for each of the first temperature, the second temperature, and the third temperature, whether an abnormality is present.

2. The battery monitoring device according to claim 1,
wherein the first temperature obtainer obtains the first temperature, based on an output signal from a thermistor provided on a surface of the battery pack.

3. The battery monitoring device according to claim 1,
wherein the second temperature obtainer obtains the second temperature, based on an impedance of each of the plurality of secondary batteries.

4. The battery monitoring device according to claim 1,
wherein the temperature distribution information includes information on an arrangement and temperatures of the plurality of secondary batteries.

5. The battery monitoring device according to claim 1,
wherein the third temperature obtainer obtains the temperature distribution information by inputting a parameter of the battery pack and a usage condition of the battery pack into a battery model created based on information on the plurality of secondary batteries.

6. The battery monitoring device according to claim 5,
wherein the information on the plurality of secondary batteries includes information on at least one of a material of each of the plurality of secondary batteries, a shape of each of the plurality of secondary batteries, an arrangement of the plurality of secondary batteries, or a cooling system of the plurality of secondary batteries.

7. The battery monitoring device according to claim 5,
wherein the parameter of the battery pack includes information on at least one of a thermal resistance parameter or a thermal capacity parameter of the battery pack.

8. The battery monitoring device according to claim 5,
wherein the usage condition of the battery pack includes at least one of a current flowing through each of the plurality of secondary batteries, a voltage applied to each of the plurality of secondary batteries, or a usage environment temperature of the battery pack.

9. The battery monitoring device according to claim 1,
wherein the determiner determines, for each of the first temperature, the second temperature, and the third temperature, whether an abnormality is present by obtaining differences among the first temperature, the second temperature, and the third temperature.

10. The battery monitoring device according to claim 1,
wherein the determiner determines that no abnormality is present in the first temperature, the second temperature, and the third temperature when differences among the first temperature, the second temperature, and the third temperature are each below a predetermined threshold.

11. The battery monitoring device according to claim 1,
wherein the determiner determines that an abnormality is present in measurement of the first temperature when a difference between the second temperature and the first temperature and a difference between the third temperature and the first temperature are each greater than or equal to a first threshold.

12. The battery monitoring device according to claim 1,
wherein the determiner determines that an abnormality is present in measurement of the second temperature when a difference between the first temperature and the second temperature and a difference between the third temperature and the second temperature are each greater than or equal to a second threshold.

13. The battery monitoring device according to claim 1,
wherein the determiner determines that the third temperature does not match an actual temperature distribution when a difference between the first temperature and the third temperature and a difference between the second temperature and the third temperature are each greater than or equal to a third threshold.

14. The battery monitoring device according to claim 1, further comprising:
a safety controller that controls operation of a relay connected in series to the battery pack, based on a determination result of the determiner.

15. The battery monitoring device according to claim 1, further comprising:
a storage that stores relational data indicating, for each of the plurality of secondary batteries, a relationship between a state of the secondary battery and a resistance component that varies with the state of the secondary battery, among a plurality of resistance components included in an impedance of the secondary battery;
an impedance obtainer that obtains an impedance of a target secondary battery for monitoring, among the plurality of secondary batteries; and
an arithmetic processer that calculates, based on the impedance obtained by the impedance obtainer, a value of a resistance component that varies with a state of the target secondary battery for monitoring, and estimates the state of the target secondary battery for monitoring, based on the value of the resistance component calculated and the relational data.

16. The battery monitoring device according to claim 15,
wherein the storage stores, as the relational data, a first relational expression indicating, for each of the plurality of secondary batteries, a relationship between an amount of capacity loss of the secondary battery and a first resistance component that varies with the amount of capacity loss of the secondary battery, and
the arithmetic processer calculates a value of the first resistance component of the target secondary battery for monitoring, based on the impedance obtained by the impedance obtainer, and estimates an amount of capacity loss of the target secondary battery for monitoring, based on the value of the first resistance component calculated and the first relational expression.

17. The battery monitoring device according to claim 15,
wherein the storage stores, as the relational data, a second relational expression indicating, for each of the plurality of secondary batteries, a relationship between an internal temperature of the secondary battery and a second resistance component that varies with the internal temperature of the secondary battery, and
the arithmetic processer calculates a value of the second resistance component of the target secondary battery for monitoring, based on the impedance obtained by the impedance obtainer, and estimates an internal temperature of the target secondary battery for monitoring, based on the value of the second resistance component calculated and the second relational expression.

18. A battery monitoring method comprising:
obtaining a first temperature that is an external temperature of a battery pack that includes a plurality of secondary batteries;
obtaining a second temperature that is an internal temperature of each of the plurality of secondary batteries;
obtaining a third temperature that includes temperature distribution information of the battery pack; and
comparing the first temperature, the second temperature, and the third temperature and determining, for each of the first temperature, the second temperature, and the third temperature, whether an abnormality is present.
